(19) United States
(12) Patent Application Publication
(10) Pub. No.: US 2025/0221067 A1
(43) Pub. Date: Jul. 3, 2025

(54) IMAGE SENSOR AND METHOD OF MANUFACTURING THE SAME

(71) Applicant: Taiwan Semiconductor Manufacturing Company, Ltd., Hsinchu (TW)

(72) Inventors: Min-Feng Kao, Chiayi City (TW); Hsing-Chih Lin, Tainan City (TW); Jen-Cheng Liu, Hsin-Chu City (TW); Dun-Nian Yaung, Taipei City (TW)

(21) Appl. No.: 18/635,103

(22) Filed: Apr. 15, 2024

Related U.S. Application Data
(60) Provisional application No. 63/614,998, filed on Dec. 27, 2023.

(51) Int. Cl. H01L 27/146

(52) U.S. Cl. CPC H10F 39/803; H10F 39/011; H10F 39/182; H10F 39/811

(57) ABSTRACT

The present disclosure relates to an image sensor integrated chip (IC) structure. The image sensor IC structure includes a plurality of image sensing elements respectively disposed within a plurality of pixel regions of a pixel array within a substrate. An inter-level dielectric (ILD) structure is disposed on a surface of the substrate and surrounds one or more interconnects. A plurality of three-dimensional (3D) capacitors are arranged within respective ones of the plurality of pixel regions and are coupled to one of the plurality of image sensing elements by the one or more interconnects. The plurality of 3D capacitors include a base region extending in parallel to the surface of the substrate and one or more fingers extending outward from the base region along a direction perpendicular to the surface of the substrate.

### REFERENCE TO RELATED APPLICATION

This application claims the benefit of U.S. Provisional Application No. 63/614,998, filed on Dec. 27, 2023, the contents of which are incorporated herein by reference in their entirety.

### BACKGROUND

Integrated circuits with image sensors are used in a wide range of modern-day electronic devices, such as cameras and cell phones, for example. In recent years, complementary metal-oxide semiconductor (CMOS) image sensors have begun to see widespread use, largely replacing charge-coupled device (CCD) image sensors. Compared to CCD image sensors, CMOS image sensors are increasingly favored due to low power consumption, a small size, fast data processing, a direct output of data, and low manufacturing cost.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of a disclosed image sensor integrated chip (IC) structure comprising a three-dimensional (3D) capacitor located within a pixel region of a pixel array.

FIG. 2 illustrates a plan-view of some embodiments of a disclosed image sensor IC structure comprising a plurality of 3D capacitors located within pixel regions of a pixel array.

FIG. 3 illustrates a cross-sectional view of some additional embodiments of a disclosed image sensor IC structure comprising a plurality of 3D capacitors located within pixel regions of a pixel array.

FIGS. 4A-4D illustrate plan-views of some embodiments of image sensor IC structures comprising 3D capacitors with fingers having different shapes.

FIG. 5 illustrates a plan-view of some additional embodiments of image sensor IC structure comprising a plurality of 3D capacitors with pixel regions of a pixel array.

FIG. 6A illustrates a cross-sectional view of some embodiments of a multi-dimensional image sensor IC structure comprising a 3D capacitor located within a pixel array.

FIGS. 6B-6C illustrate circuit diagrams of some embodiments of image sensor IC circuits comprising a 3D capacitor located within a pixel array.

FIGS. 7A-10C illustrate some embodiments of cross-sectional views of 3D capacitors arranged at different locations within multi-dimensional image sensor IC structures.

FIGS. 11A-11B illustrate some additional embodiments of cross-sectional views of 3D capacitors arranged at different locations within multi-dimensional image sensor IC structures.

FIGS. 12A-12C illustrate some embodiments of cross-sectional views of disclosed 3D capacitors having different heights.

FIGS. 13-20 illustrate cross-sectional views of some embodiments of a method of forming a 3D capacitor within a pixel region of an image sensor IC structure.

FIGS. 21-28 illustrate cross-sectional views of some additional embodiments of a method of forming a 3D capacitor within a pixel region of an image sensor IC structure.

FIGS. 29-36 illustrate cross-sectional views of some additional embodiments of a method of forming a 3D capacitor within a pixel region of an image sensor IC structure.

FIG. 37 illustrates a flow diagram of some embodiments of a method of forming a 3D capacitor within a pixel region of an image sensor IC structure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Image sensor integrated chip (IC) structures include CMOS image sensors (CIS) comprising a plurality of pixel regions arranged in a pixel array. The plurality of pixel regions respectively include an image sensing element arranged within a semiconductor substrate and laterally surrounded by isolation structures that are configured to electrically isolate adjacent pixel regions. A plurality of micro-lenses may be arranged over the plurality of pixel regions. The plurality of micro-lenses are respectively configured to focus incident radiation (e.g., light) onto an underlying image sensing element. Upon receiving the incident radiation, the image sensing element is configured to convert the incident radiation into an electric signal. The electric signal from the image sensing element can be processed by a signal processing unit to determine an image captured by the CIS.

As technology has advanced, the demands placed on CIS have increased. For example, in recent years CIS have become an integral part of developments in machine vision applications, automotive applications, and the like. In such applications, the well-being of humans may be on the line, and therefore the CIS used have to provide for accurate image sensing over a wide range of illumination conditions (e.g., achieving a wide dynamic range performance while maintaining a good signal to noise ratio). To achieve improved performance, many modern-day CIS structures use capacitors. For example, some CIS structures use capacitors to achieve a global shutter behavior, which allows for each pixel in a pixel array to simultaneously transfer its charge to a memory within the pixel, thereby providing a faster frame rate that can improve low-light performance.

As sizes of integrated chips scale (e.g., decrease), sizes of pixel regions within the integrated chips have also scaled (e.g., decreased). However, a capacitance of a planar capacitor (e.g., 2-dimensional capacitor) cannot scale without decreasing a value of the capacitance. This is because a capacitance of a planar capacitor is proportional to an area of the planar capacitor's electrodes divided by a distance between the electrodes. As sizes of pixel regions get smaller (e.g., less than approximately 0.5 um, less than approximately 0.3 um), it becomes increasingly difficult to fit a planar capacitor into a pixel region, while still providing a capacitance value that enables good performance of an associated image sensing integrated chip.

The present disclosure relates to an image sensor integrated chip (IC) structure comprising three-dimensional (3D) capacitors located within pixel regions of a pixel array. In some embodiments, a disclosed image sensor IC structure may comprise a plurality of image sensing elements respectively disposed within a plurality of pixel regions of a pixel array within a substrate. An inter-level dielectric (ILD) structure is disposed on a surface of the substrate and surrounds one or more interconnects. A plurality of three-dimensional (3D) capacitors are arranged within a respective one of the plurality of pixel regions and are respectively coupled to one of the plurality of image sensing elements by the one or more interconnects. The plurality of 3D capacitors include a base region extending in parallel to the surface of the substrate and one or more fingers extending outward from the base region along a direction perpendicular to the surface of the substrate. By having the plurality of 3D capacitors extending in parallel to and perpendicular to the surface, surface areas of the plurality of 3D capacitors can be increased while still arranging the plurality of 3D capacitors within one of the plurality of pixel regions. The increased capacitances of the plurality of 3D capacitors can improve a performance of the image sensor IC structure (e.g., provide for a higher dynamic range, a lower KTC noise, etc.)

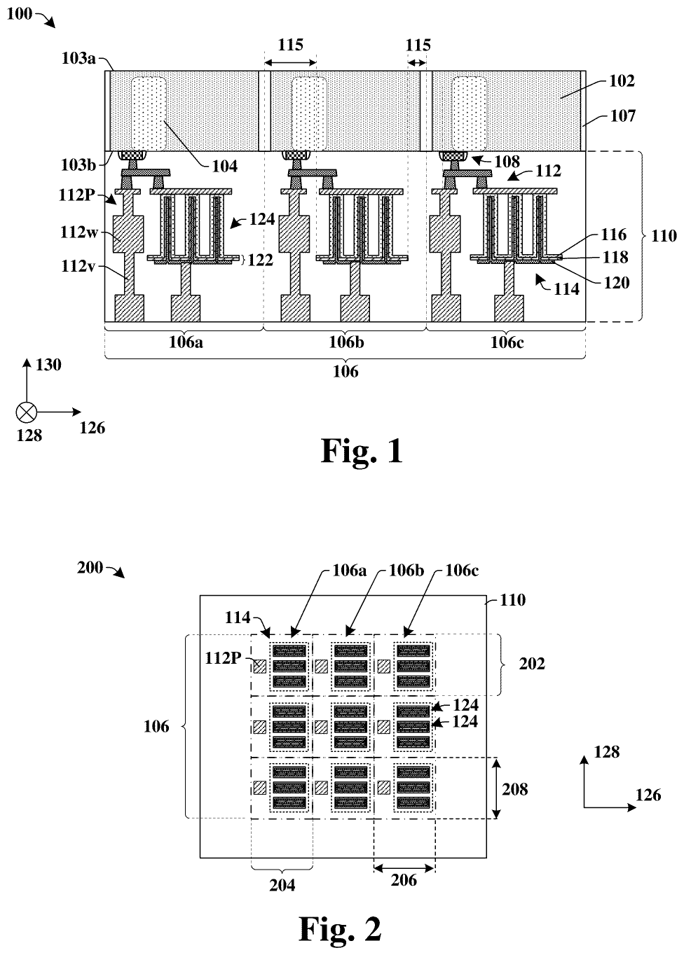

FIG. 1 illustrates a cross-sectional view of some embodiments of a disclosed image sensor IC structure 100 comprising a 3D capacitor located within a pixel region of a pixel array.

The image sensor IC structure 100 comprises a plurality of image sensing elements 104 (e.g., photodiodes) disposed within a substrate 102. The substrate 102 has a first surface 103a configured to receive incident radiation and a second surface 103b opposing the first surface 103a. One or more gate structures 108 (e.g., transfer gates) are disposed on the second surface 103b. During operation, the plurality of image sensing elements 104 are respectively configured to generate a current in response to incident radiation. The current is provided from the plurality of image sensing elements 104 to the one or more gate structures 108.

The plurality of image sensing elements 104 are disposed within a pixel array 106 comprising a plurality of pixel regions 106a-106c. In some embodiments, the plurality of image sensing elements 104 within respective ones of the plurality of pixel regions 106a-106c may be laterally separated from one another by way of one or more isolation structures 107 disposed within the substrate 102. In some embodiments, the one or more isolation structures 107 may comprise an insulating material (e.g., silicon dioxide) arranged between sidewalls of the substrate 102.

An inter-level dielectric (ILD) structure 110 is disposed on the second surface 103b of the substrate 102. The ILD structure 110 surrounds a plurality of interconnects 112. One or more of the plurality of interconnects 112 are electrically coupled to the one or more gate structures 108. The ILD structure 110 also surrounds a plurality of three-dimensional (3D) capacitors 114. In some embodiments, the plurality of 3D capacitors 114 are respectively disposed within one of the plurality of pixel regions 106a-106b (e.g., directly below one of the plurality of image sensing elements 104). For example, a first 3D capacitor is arranged within a first pixel region 106a, a second 3D capacitor is arranged within a second pixel region 106b, etc. In some embodiments, the plurality of 3D capacitors 114 are entirely confined within an overlying one of the plurality of pixel regions 106a-106b. In some embodiments, the plurality of 3D capacitors 114 may be laterally separated from opposing edges of a corresponding pixel region (e.g., a directly overlying pixel region) by non-zero distances 115.

In some embodiments, the ILD structure 110 may laterally separate the plurality of 3D capacitors 114 from a peripheral interconnect structure 112P within a same pixel region. In some embodiments, the peripheral interconnect structure 112P comprises a conductive via 112v. The plurality of 3D capacitors 114 vertically extend from below a top of the conductive via 112v to below a bottom of the conductive via 112v. In some embodiments, the peripheral interconnect structure 112P may further comprise an interconnect wire 112w having a larger width than the conductive via 112v. The plurality of 3D capacitors 114 vertically extend from above a top of the interconnect wire 112w to below a bottom of the interconnect wire 112w.

The plurality of 3D capacitors 114 respectively comprise a first electrode 116 separated from a second electrode 120 by a capacitor dielectric 118 along a first direction 126, along a second direction 128, and along a third direction 130 that is perpendicular to the first direction 126 and the second direction 128. The first electrode 116, the second electrode 120, and the capacitor dielectric 118 are arranged within a base region 122 and within one or more fingers 124 extending outward from the base region 122 along a direction perpendicular to the second surface 103b of the substrate 102. Within the base region 122, the first electrode 116 and the second electrode 120 extend along a plane extending in the first direction 126 and in the second direction 128. Within the one or more fingers 124, the first electrode 116 and the second electrode 120 extend outward from the plane in the third direction 130.

By having the first electrode 116 and second electrode 120 separated from one another along the first direction 126, the second direction 128, and the third direction 130, surface areas of the first electrode 116 and the second electrode 120 can be increased without increasing a footprint of respective ones of the plurality of 3D capacitors 114. By increasing surface areas of the first electrode 116 and the second electrode 120, capacitances of the plurality of 3D capacitors 114 can be increased while still arranging the plurality of 3D capacitors 114 within one of the plurality of pixel regions 106a-106c. The increased capacitances of the plurality of 3D capacitors can provide for a relatively high capacitance density within pixel arrays having small pixel areas (e.g., pixel areas that are between approximately 0.5 microns (μm) and approximately 3 μm). The relatively high capacitance allows for the disclosed capacitors to improve pixel array performance (e.g., a higher dynamic range, a lower KTC noise, etc.) and/or be implemented within a wide range of image sensor circuitry (e.g., a global shutter circuit, a CDS circuit, a lateral overflow integration capacitor (LOFIC) pixel, and/or the like).

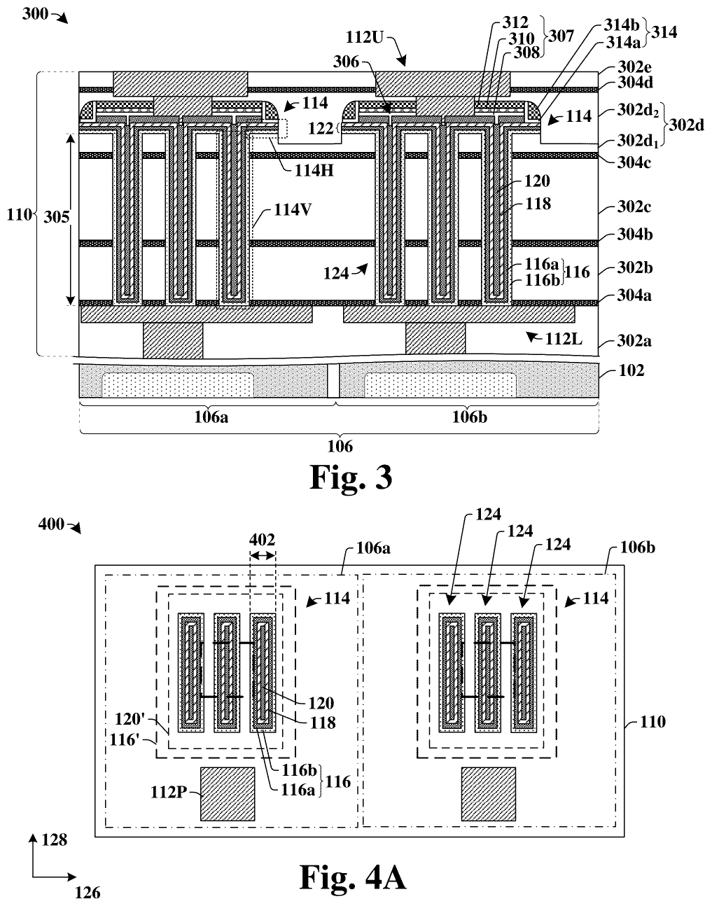

FIG. 2 illustrates a plan-view of some embodiments of a disclosed image sensor IC structure 200 comprising a plurality of 3D capacitors located within pixel regions of a pixel array.

The image sensor IC structure 200 comprises a plurality of pixel regions 106a-106c arranged within a pixel array 106 having rows 202 and columns 204. The rows 202 extend in a first direction 126 and the columns 204 extend in a second direction 128 that is perpendicular to the first direction 126 in the plan-view. In some embodiments, the plurality of pixel regions 106a-106c may respectively have a length 206 and a width 208 that are between approximately 0.5 microns (μm) and approximately 3 μm, between approximately 0.5 μm and approximately 10 μm, or other similar values.

Each of the plurality of pixel regions 106a-106c comprises one of a plurality of 3D capacitors 114 and a peripheral interconnect structure 112P. The plurality of 3D capacitors 114 respectively comprise one or more fingers 124 that are separated from one another by an ILD structure 110. The peripheral interconnect structure 112P extends through the ILD structure 110 at a location that is separated from the plurality of 3D capacitors 114.

FIG. 3 illustrates a cross-sectional view of some additional embodiments of a disclosed image sensor IC structure 300 comprising a plurality of 3D capacitors located within pixel regions of a pixel array.

The image sensor IC structure 300 comprises an ILD structure 110 disposed on a substrate 102. The ILD structure 110 comprises a plurality of inter-level dielectric (ILD) layers 302a-302e alternatingly stacked with a plurality of etch stop layers 304a-304d. In some embodiments, the ILD structure 110 may comprise a first ILD layer 302a separated from a second ILD layer 302b by a first ESL 304a, a third ILD layer 302c separated from the second ILD layer 302b by a second ESL 304b, a lower fourth ILD layer 302d₁ and an upper fourth ILD layer 302d₂ separated from the third ILD layer 302c by a third ESL 304c, and a fifth ILD layer 302e separated from the upper fourth ILD layer 302d₂ by a fourth ESL 304d. In some embodiments, the first ILD layer 302a may be separated from the substrate 102 by one or more underlying ILD layers (not shown). A lower interconnect structure 112L is arranged within the first ILD layer 302a. The lower interconnect structure 112L may comprise an interconnect wire and/or an interconnect via.

In some embodiments, the plurality of ILD layers 302a-302e may respectively comprise an oxide (e.g., silicon dioxide), a nitride (e.g., silicon nitride, silicon oxynitride), a carbide (e.g., silicon carbide), borosilicate glass (BSG), phosphoric silicate glass (PSG), borophosphosilicate glass (BPSG), a low-k oxide (e.g., a carbon doped oxide, SiCOH), and/or the like. In some embodiments, the first ILD layer 302a may have a first thickness (e.g., between 6,000 Å and 7000 Å, approximately 6,200 Å, or other similar values), the second ILD layer 302b may have a second thickness (e.g., between 6,000 Å and 7000 Å, approximately 6,200 Å, or other similar values), the third ILD layer 302c may have a third thickness (e.g., between 8,000 Å and 9,000 Å, approximately 8,500 Å, or other similar values), the fourth ILD layer 302d may have a fourth thickness (e.g., between 6,000 Å and 7000 Å, approximately 6,200 Å, or other similar values), and the fifth ILD layer 302e may have a fifth thickness (e.g., between 6,000 Å and 7000 Å, approximately 6,200 Å, or other similar values).

In some embodiments, the one or more etch stop layers 304a-304d may comprise silicon nitride, silicon carbide, and/or the like. In some embodiments, the one or more etch stop layers 304a-304d may respectively have a thickness of between approximately 200 Å and approximately 700 Å, approximately 500 Å, or other similar values.

A plurality of 3D capacitors 114 are arranged on the lower interconnect structure 112L. The plurality of 3D capacitors 114 comprise a horizontally extending segment 114H and a vertically extending segment 114V. The vertically extending segment 114V extends outward from a bottom of the horizontally extending segment 114H and through the one or more of the plurality of ILD layers 302a-302e. The plurality of 3D capacitors 114 respectively comprise a lower surface arranged between an outermost sidewall and an outer sidewall facing a same direction.

In some embodiments, the plurality of 3D capacitors 114 comprise a first electrode 116 separated from a second electrode 120 by a capacitor dielectric 118. In some embodiments, the first electrode 116 may comprise a capacitor barrier 116b and a lower capacitor metal 116a over the capacitor barrier 116b. In some embodiments, the first electrode 116 and the second electrode 120 may have a thickness that is in a range of between approximately 50 Angstroms (Å) and approximately 1000 Å. In some embodiments, the capacitor dielectric 118 may have a thickness that is in a range of between approximately 20 Å and approximately 100 Å.

The first electrode 116 and the second electrode 120 are respectively disposed within a base region 122 and one or more fingers 124 of the 3D capacitor 114. In some embodiments, the base region 122 is arranged above the lower fourth ILD layer 302d₁. The one or more fingers 124 extend outward from a bottom of the base region 122 and through the second ILD layer 302b, the third ILD layer 302c, and the lower fourth ILD layer 302d₁. In some embodiments, the one or more fingers 124 may respectively have a height 305 that is in a range of between approximately 0.5 μm and approximately 5 μm.

The second electrode 120 may be laterally set-back from outermost sidewalls of the first electrode 116 and the capacitor dielectric 118. In some embodiments, the second electrode 120 may comprise recesses 306 arranged along a top of the second electrode 120 and directly over the plurality of fingers 124. A capacitor cap 307 covers the top of the second electrode 120 and extends into the recesses 306. In some embodiments, the capacitor cap 307 may comprise a first upper dielectric 308, a second upper dielectric 310 over the first upper dielectric 308, and a third upper dielectric 312 over the second upper dielectric 310.

In some embodiments, the first upper dielectric 308 may comprise an oxide (e.g., silicon oxy-nitride, silicon oxide, or the like). In some embodiments, the second upper dielectric 310 may comprise silicon oxy-nitride, or the like. In some embodiments, the second upper dielectric 310 may have a thickness that is in a range of between approximately 100 Å and approximately 400 Å, approximately 300 Å, or other similar values. In some embodiments, the third upper dielectric 312 may comprise silicon nitride, or the like. In some embodiments, the third upper dielectric 312 may have a thickness that is in a range of between approximately 750 Å and approximately 1200 Å, approximately 950 Å, or other similar values.

In some embodiments, one or more sidewall spacers 314 are arranged vertically over the capacitor dielectric 118 and laterally between outermost sidewalls of the capacitor dielectric 118 and the second electrode 120. The one or more sidewall spacers 314 may cover sidewalls of the capacitor cap 307. In some embodiment, the one or more sidewall spacers 314 may comprise a first dielectric spacer layer 314a and a second dielectric spacer layer 314b.

In some embodiments, the outermost sidewalls of the first electrode 116 and the capacitor dielectric 118 may be laterally aligned (e.g., co-planar) with a sidewall of the lower fourth ILD layer 302d₁. In such embodiments, the lower fourth ILD layer 302d₁ has a larger thickness directly below the plurality of 3D capacitors 114 than laterally outside of the plurality of 3D capacitors 114.

An upper interconnect structure 112U is arranged within the upper fourth ILD layer 302d₂ and the fifth ILD layer 302e. The upper interconnect structure 112U extends through the capacitor cap 307 to contact the second electrode 120.

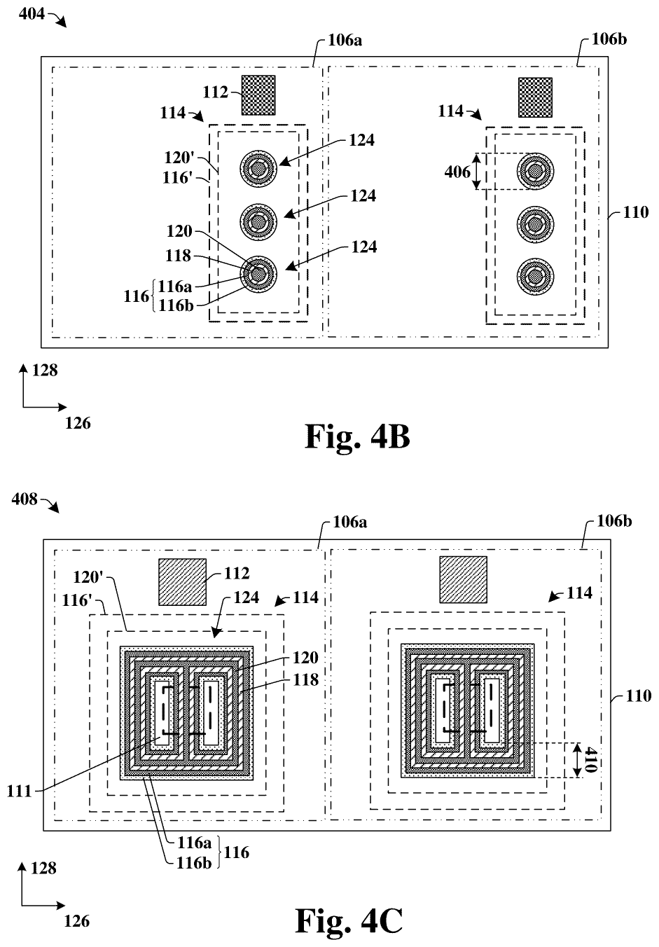

It will be appreciated that the one or more fingers of the disclosed 3D capacitor may have various shapes and/or configurations. The different shapes and/or configuration allow for different capacitance values to be achieved and/or for interconnect routing flexibility. FIGS. 4A-4C illustrate some embodiments of plan-views of image sensor IC structures having different arrangements of fingers. The plan-views shown in FIGS. 4A-4C are not limiting, but are merely examples of some arrangements of the fingers.

FIG. 4A illustrates a plan-view of some embodiments of an image sensor IC structure 400 having 3D capacitors with rectangular shaped fingers.

The image sensor IC structure 400 includes pixel regions 106a-106b within an ILD structure 110 on a substrate. A plurality of 3D capacitors 114 are disposed within the pixel regions 106a-106b and are surrounded by the ILD structure 110. The plurality of 3D capacitors 114 comprise a first electrode 116 separated from a second electrode 120 by a capacitor dielectric 118. Outlines of outermost perimeters of top surfaces of the first electrode 116′ and the second electrode 120′ are shown in phantom. A plurality of fingers 124 are below the top surfaces of the first electrode 116 and the second electrode 120. The plurality of fingers 124 have a rectangular shape that extends for a smaller length in a first direction 126 than in a second direction 128. Within respective ones of the plurality of fingers 124, the first electrode 116 is separated from the second electrode 120 by the capacitor dielectric 118. In some embodiments, respective ones of the plurality of fingers 124 may have a width 402 measured along the first direction 126 that is in a range of between approximately 0.01 μm and approximately 10 μm, between approximately 1 μm and approximately 10 μm, or other similar values.

FIG. 4B illustrates a plan-view of some embodiments of an image sensor IC structure 404 having 3D capacitors with circular shaped fingers.

The image sensor IC structure 404 includes pixel regions 106a-106b within an ILD structure 110 on a substrate. A plurality of 3D capacitors 114 are disposed within respective ones of the pixel regions 106a-106b. The plurality of 3D capacitors 114 comprise a plurality of fingers 124 below top surfaces of a first electrode 116 and a second electrode 120. The plurality of fingers 124 are separated from one another along a first direction 126. The plurality of fingers 124 respectively have a circular shape. In some embodiments, respective ones of the plurality of fingers 124 may have a width 406 measured along the second direction 128 that is in a range of between approximately 0.01 μm and approximately 10 μm, between approximately 1 μm and approximately 10 μm, or other similar values.

FIG. 4C illustrates a plan-view of some embodiments of an image sensor IC structure 408 having 3D capacitors with fingers enclosing a column of an inter-level dielectric.

The image sensor IC structure 408 includes pixel regions 106a-106b within an ILD structure 110 on a substrate. A plurality of 3D capacitors 114 are disposed within respective ones of the pixel regions 106a-106b. The plurality of 3D capacitors 114 comprise a finger 124 arranged below top surfaces of a first electrode 116 and a second electrode 120. The finger 124 has an enclosed shape that continuously wraps around one or more columns 111 of the ILD structure 110 that are directly below the top surfaces of the first electrode 116 and the second electrode 120. Within the finger 124, parts of the first electrode 116, the second electrode 120, and the capacitor dielectric 118 may concentrically surround the one or more columns 111 of the ILD structure 110.

In some embodiments, the finger 124 comprises segments extending in a first direction 126 coupled to segments extending in a second direction 128. In some embodiments, the segments extending in the first direction 126 may have a width 410 measured along the second direction 128 that is in a range of between approximately 0.01 μm and approximately 10 μm, between approximately 1 μm and approximately 10 μm, or other similar values.

FIG. 4D illustrates a plan-view of some embodiments of an image sensor IC structure 412 having 3D capacitors with fingers enclosing a column of an inter-level dielectric.

The image sensor IC structure 412 includes pixel regions 106a-106b within an ILD structure 110 on a substrate. A plurality of 3D capacitors 114 are disposed within respective ones of the pixel regions 106a-106b. The plurality of 3D capacitors 114 comprise a finger 124 arranged below top surfaces of a first electrode 116 and a second electrode 120. The finger 124 has an enclosed shape that continuously wraps around one or more columns 111 of the ILD structure 110 that are directly below the top surfaces of the first electrode 116 and the second electrode 120. In some embodiments, the finger 124 comprises segments extending in a first direction 126 coupled to segments extending in a second direction 128.

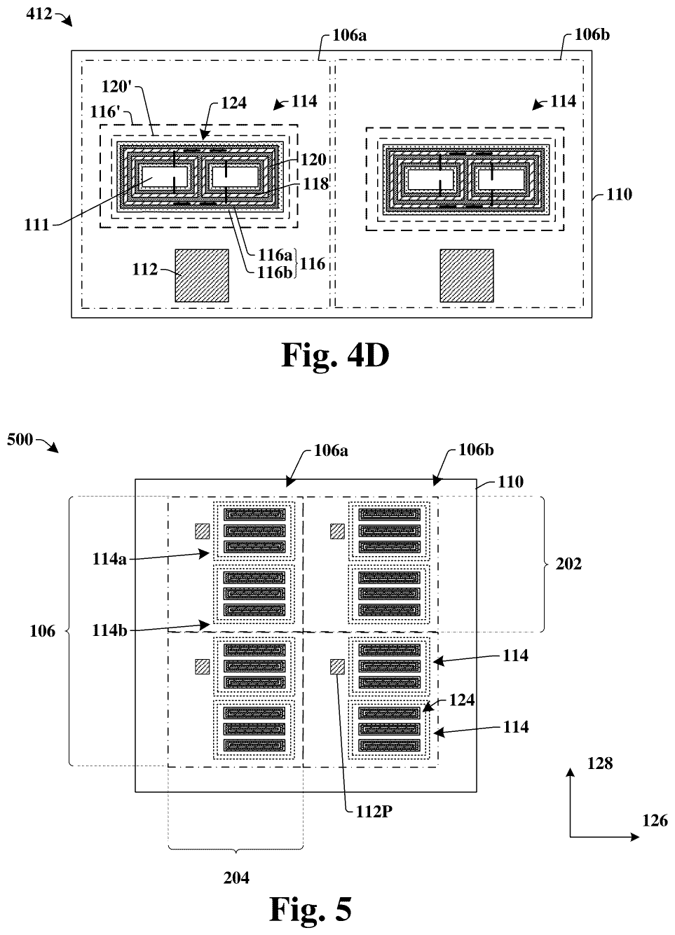

FIG. 5 illustrates a plan-view of some additional embodiments of an image sensor IC structure 500 comprising 3D capacitors located within a pixel array.

The image sensor IC structure 500 comprises a plurality of pixel regions 106a-106b arranged within a pixel array 106 having rows 202 and columns 204. The rows 202 extend in a first direction 126 and the columns 204 extend in a second direction 128 that is perpendicular to the first direction 126 in the plan-view.

Each of the plurality of pixel regions 106a-106b comprises two or more of a plurality of 3D capacitors 114 and a peripheral interconnect structure 112P that is separated from the plurality of 3D capacitors 114 by the ILD structure 110. For example, a first pixel region 106a comprises a first 3D capacitor and a second 3D capacitor separated by the ILD structure 110. The plurality of 3D capacitors 114 respectively comprise one or more fingers 124 that are separated from one another by an ILD structure 110.

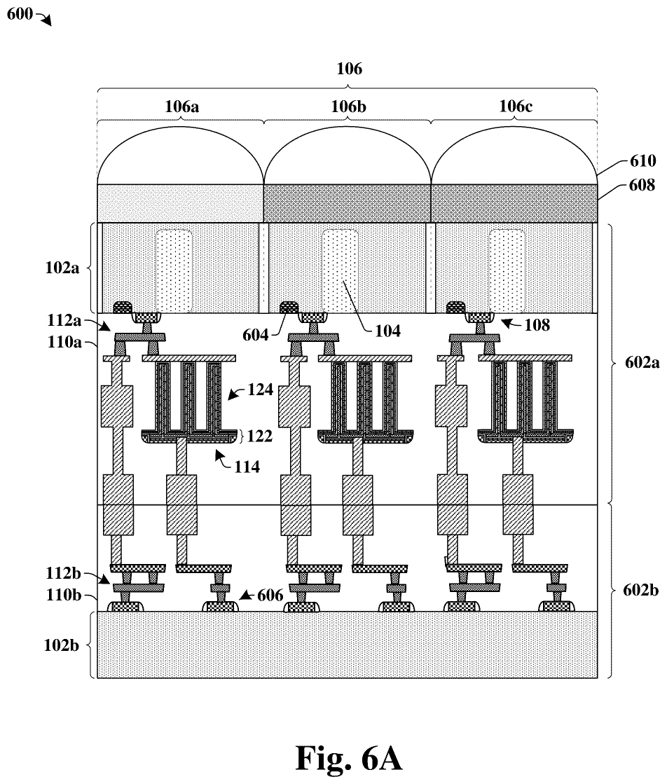

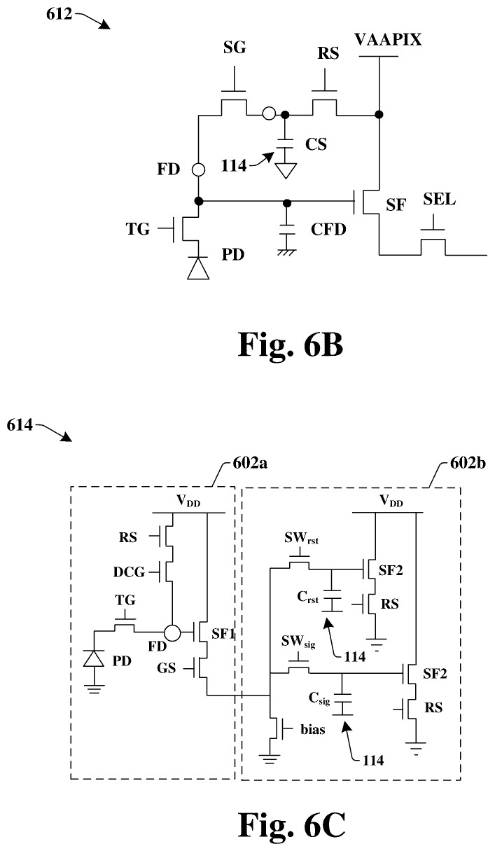

FIG. 6A illustrates a cross-sectional view of some embodiments of a multi-dimensional image sensor IC structure 600 comprising 3D capacitors located within a pixel array.

The multi-dimensional image sensor IC structure 600 comprises a plurality of integrated chip (IC) tiers 602a-602b stacked onto one another. In some embodiments, the multi-dimensional image sensor IC structure 600 may comprise a three-dimensional integrated chip (3DIC) structure. In some embodiments, the plurality of IC tiers 602a-602c comprise a first tier 602a and a second tier 602b. In some additional embodiments, the plurality of IC tiers 602a-602c comprise additional tiers (e.g., a third tier, a fourth tier, etc.)

The first tier 602a comprises a plurality of image sensing elements 104 disposed within a first substrate 102a. The plurality of image sensing elements 104 are disposed within a pixel array 106 comprising a plurality of pixel regions 106a-106c. In some embodiments a floating diffusion region 604 may also be disposed within the first substrate 102a. A plurality of gate structures 108 are disposed on and/or within the first substrate 102a between one of the plurality of image sensing elements 104 and the floating diffusion region 604. A first ILD structure 110a is also disposed on the first substrate 102a. The first ILD structure 110a surrounds a first plurality of interconnects 112a. One or more of the first plurality of interconnects 112a are electrically coupled to the plurality of gate structures 108.

The second tier 602b comprises a plurality of pixel support devices 606 disposed on and/or within a second substrate 102b. In some embodiments, the plurality of pixel support devices 606 may comprise one or more of a reset transistor, a source-follower transistor, a row-select transistor, and/or the like. In other embodiments, the plurality of pixel support devices 606 may comprise transistors configured to operate as an analog-to-digital converter, an amplifier, a multiplexor, a correlated double sampling circuit, a global shutter circuit, a lateral overflow integration capacitor (LOFIC) pixel, and/or the like. The plurality of pixel support devices 606 are connected to a second ILD structure 110b surrounding a second plurality of interconnects 112b. In various embodiments, the plurality of pixel support devices 606 may comprise a planar FET, a FinFET, a gate all around (GAA) transistor, a nanosheet transistor, and/or the like. In some embodiments, the first ILD structure 110a is bonded to the second ILD structure 110b along a bonding interface comprising one or more conductive interfaces and one or more dielectric interfaces.

A plurality of color filters 608 are disposed on a back-side of the first substrate 102a and a plurality of micro-lenses 610 are arranged on the plurality of color filters 608. The plurality of micro-lenses 610 respectively and directly overlie the plurality of image sensing elements 104 within one of the plurality of pixels regions 106a-106c.

It will be appreciated that the disclosed 3D capacitors can be used in a wide range of image sensing applications. FIGS. 6B-6C illustrate two exemplary circuit diagrams showing applications of the disclosed 3D capacitors. It will be appreciated that the examples are non-limiting examples and that the disclosed 3D capacitors may also be used in other applications.

In some embodiments, shown in an exemplary circuit diagram 612 of FIG. 6B, the plurality of 3D capacitors 114 in the multi-dimensional image sensor IC structure may be implemented within lateral overflow integration capacitor (LOFIC) pixels. In some such embodiments, the plurality of 3D capacitors 114 may be configured to operate as a charge storage capacitor CS within each pixel region. The charge storage capacitor CS and a charge storage gate SG are arranged between a floating diffusion node FD and a reset transistor RS. In some embodiments, the floating diffusion node FD may be arranged in the first tier 602a and the reset transistor RS may be arranged in the second tier 602b.

During an exposure period of operation, the electric potential heights of the transfer gate TG and the charge storage gate SG are designed such that once the photodiode PD is saturated, overflow charges from the photodiode PD will accumulate in a floating diffusion capacitor (CFD). When the floating diffusion node FD is saturated, excess charge will flow into the charge storage capacitor CS through the charge storage gate SG. Therefore, the LOFIC pixel is configured to accumulate charges after the photodiode PD is saturated so as to allow for a high dynamic range.

In some embodiments, shown in an exemplary circuit diagram 614 of FIG. 6C, the plurality of 3D capacitors 114 in the multi-dimensional image sensor IC structure may be implemented within a global shutter scheme. In some such embodiments, the plurality of 3D capacitors 114 may be configured to operate as a reset capacitor Cᵣₛₜ and a signal capacitor C_{sig}. The reset capacitor Cᵣₛₜ is configured to store a reset value. The signal capacitor C_{sig} is configured to store a signal value. During operation, in order to cancel reset noise, within a pixel a reset value and a signal value are sampled onto Cᵣₛₜ and C_{sig}. The sampled values are used to generate a sampling noise that is inversely proportional to a size of Cᵣₛₜ and C_{sig}.

In some embodiments, the photodiode PD may be arranged in a first tier 602a and the reset capacitor Cᵣₛₜ and the signal capacitor C_{sig} may be arranged in a same pixel region of a second tier 602b. In other embodiments, the photodiode PD and the reset capacitor Cᵣₛₜ may be arranged in the first tier 602a and the signal capacitor C_{sig} may be arranged in a same pixel region of the second tier 602b.

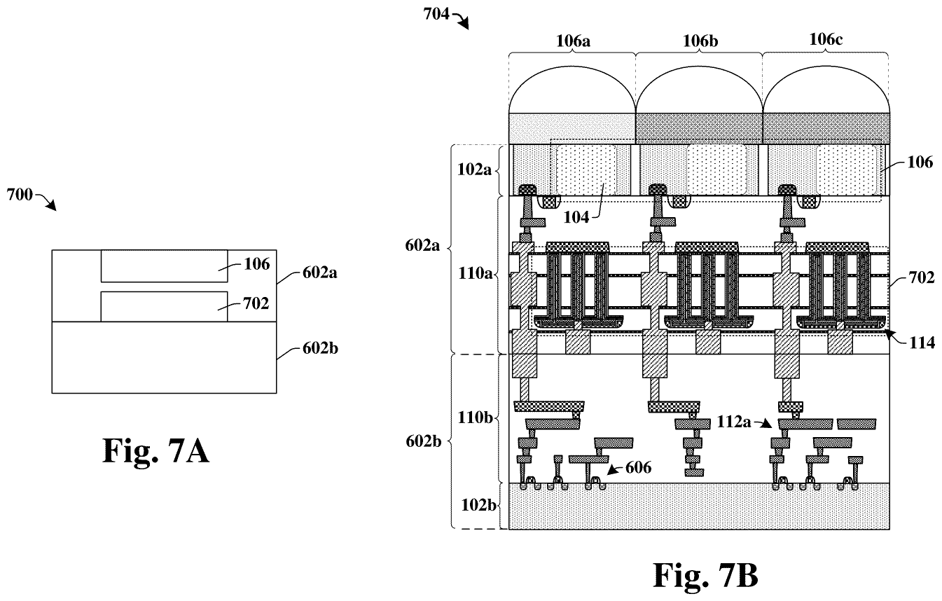

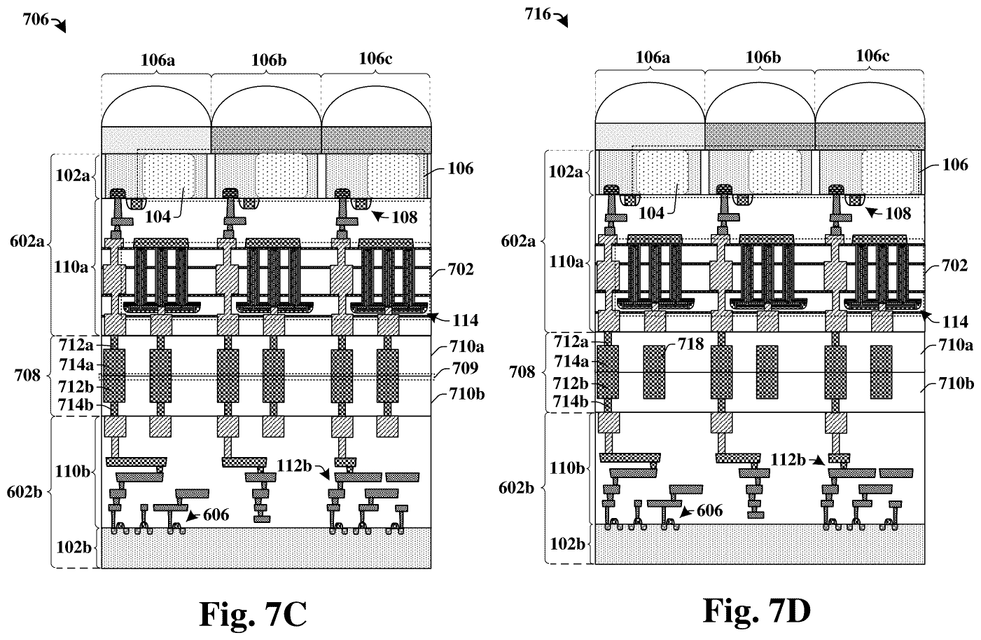

Although the three-dimensional capacitor is illustrated in FIG. 6A as being within a first tier, it will be appreciated that the disclosed three-dimensional capacitor may be arranged at different locations within a multi-dimensional image sensor IC structure. For example, FIGS. 7A-11B illustrate some embodiments of multi-dimensional image sensor IC structure arranged at different locations within a multi-dimensional image sensor IC structure. The embodiments shown in FIGS. 7A-11B are not limiting, but are merely examples of some multi-dimensional image sensor IC structures.

FIG. 7A illustrates a block diagram of a multi-dimensional integrated chip structure 700 having a three-dimensional capacitor array arranged within a first tier.

The multi-dimensional integrated chip structure 700 comprises a first tier 602a and a second tier 602b stacked onto the first tier 602a. The first tier 602a includes a pixel array 106 comprising a plurality of image sensing elements (e.g., photodiodes) within a plurality of pixel regions. The first tier 602a further includes a 3D capacitor array 702 comprising a plurality of 3D capacitors.

FIG. 7B illustrates a cross-sectional view of some additional embodiments of a multi-dimensional integrated chip structure 704 having three-dimensional capacitors arranged within a first tier.

The multi-dimensional integrated chip structure 704 comprises a first tier 602a stacked onto a second tier 602b. The first tier 602a includes a first ILD structure 110a disposed on a first substrate 102a. A plurality of image sensing elements 104 are disposed within the first substrate 102a in a pixel array 106 having a plurality of pixel regions 106a-106c. A 3D capacitor array 702 is disposed within the first ILD structure 110a. The 3D capacitor array 702 comprises a plurality of 3D capacitors 114 respectively disposed within one of the plurality of pixel regions 106a-106c. The plurality of 3D capacitors 114 are arranged between a top and a bottom of the first ILD structure 110a. In some embodiments, the second tier 602b may comprise one or more pixel support devices 606 (e.g., for a CIS circuit, a CDS circuit, a global shutter circuit, a LOFIC circuit, etc.).

FIG. 7C illustrates a cross-sectional view of some additional embodiments of a multi-dimensional integrated chip structure 706 having 3D capacitors arranged within a first tier.

The multi-dimensional integrated chip structure 706 comprises a first tier 602a stacked onto a second tier 602b. The first tier 602a includes a pixel array 106 having a plurality of pixel regions 106a-106c within a first substrate 102a. The first tier 602a further includes a 3D capacitor array 702 comprising a plurality of 3D capacitors 114 arranged within a first ILD structure 110a on the first substrate 102a. The second tier 602b includes one or more pixel support devices 606.

The first tier 602a is coupled to the second tier 602b by a bonding region 708 having a bonding interface 709 that includes both conductive interfaces and dielectric interfaces. In some embodiments, the bonding region 708 includes first bond connects 712a and first bond links 714a disposed within a first insulating layer 710a. The first bond connects 712a are connected between the plurality of 3D capacitors 114 and the first bond links 714a. In some embodiments, one or more of the first bond connects 712a and the first bond links 714a are arranged directly below the plurality of 3D capacitors 114. The bonding region 708 further includes second bond connects 712b and second bond links 714b disposed within a second insulating layer 710b. The first bond links 714a are connected to the second bond links 714b along the bonding interface 709.

FIG. 7D illustrates a cross-sectional view of some additional embodiments of a multi-dimensional integrated chip structure 716 having 3D capacitors arranged within a first tier.

The multi-dimensional integrated chip structure 716 comprises a first tier 602a coupled to the second tier 602b by a bonding region 708. The bonding region 708 includes first bond connects 712a, first bond links 714a, second bond connects 712b, and second bond links 714b that are laterally outside of a plurality of 3D capacitors 114. The bonding region 708 further includes one or more dummy bond links 718 disposed directly below the plurality of 3D capacitors 114. The one or more dummy bond links 718 are configured to provide for a sufficient metal density for planarization of the first insulating layer 710a and the second insulating layer 710b.

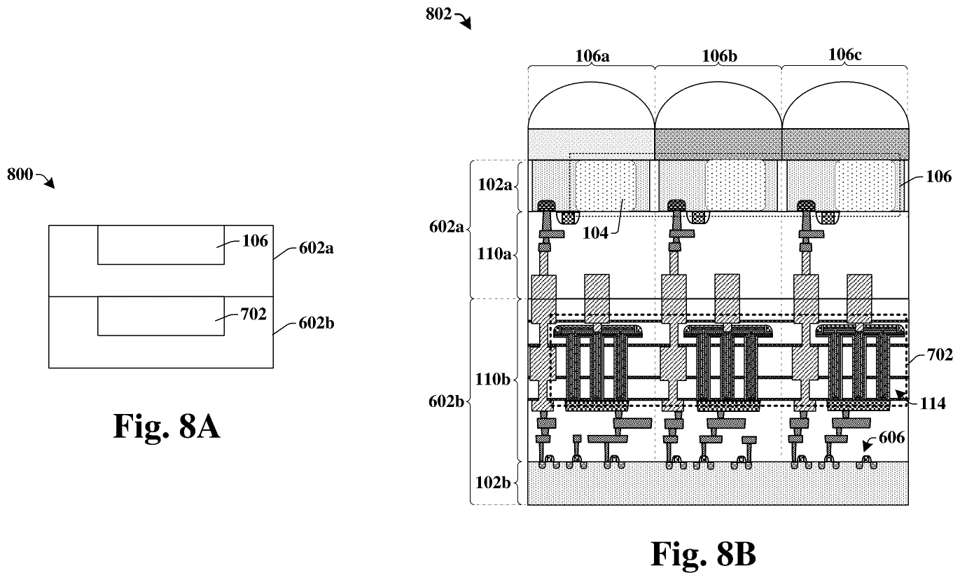

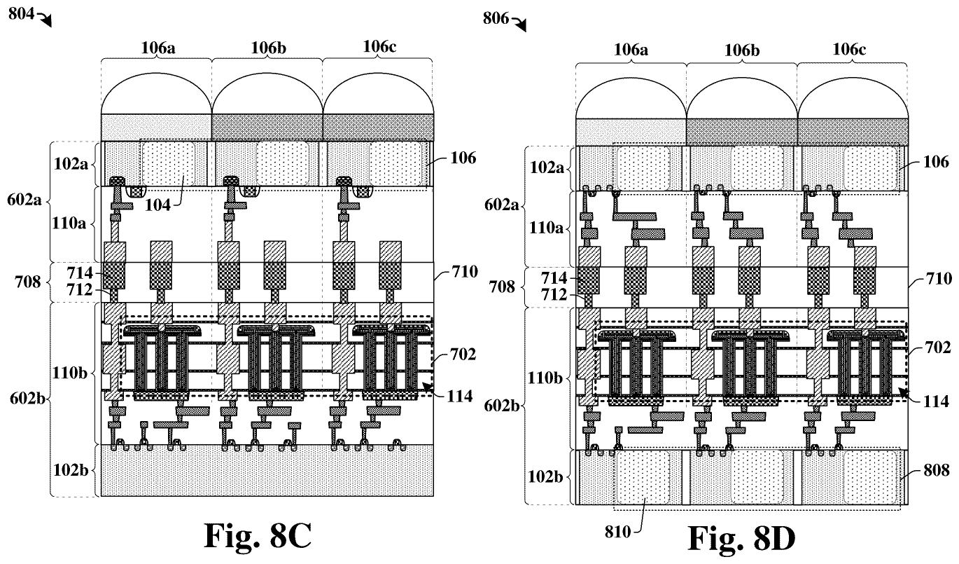

FIG. 8A illustrates a block diagram of a multi-dimensional integrated chip structure 800 having a three-dimensional capacitor array arranged within a second tier.

The multi-dimensional integrated chip structure 800 comprises a first tier 602a and a second tier 602b stacked onto the first tier 602a. The first tier 602a includes a pixel array 106 comprising a plurality of image sensing elements (e.g., photodiodes) within a plurality of pixel regions. The second tier 602b includes a 3D capacitor array 702 comprising a plurality of 3D capacitors.

FIG. 8B illustrates a cross-sectional view of a multi-dimensional integrated chip structure 802 having three-dimensional capacitors arranged within a second tier.

The multi-dimensional integrated chip structure 802 comprises a first tier 602a and a second tier 602b stacked onto the first tier 602a. The first tier 602a includes a plurality of image sensing elements 104 disposed within the first substrate 102a in a pixel array 106 having a plurality of pixel regions 106a-106c. A first ILD structure 110a is disposed on a first substrate 102a. The second tier 602b includes a second ILD structure 110b disposed on a second substrate 102b. A 3D capacitor array 702 is disposed within the second ILD structure 110b. The 3D capacitor array 702 comprises a plurality of 3D capacitors 114 respectively disposed within one of the plurality of pixel regions 106a-106c. The plurality of 3D capacitors 114 are arranged between a top and a bottom of the second ILD structure 110b. In some embodiments, the second tier 602b may further comprise one or more pixel support devices 606 (e.g., for a CIS circuit, a CDS circuit, a global shutter circuit, a LOFIC circuit, etc.).

FIG. 8C illustrates a cross-sectional view of some additional embodiments of a multi-dimensional integrated chip structure 804 having three-dimensional capacitors arranged within a second tier.

The multi-dimensional integrated chip structure 804 comprises a first tier 602a stacked on a second tier 602b. The first tier 602a includes a pixel array 106 having a plurality of pixel regions 106a-106c within a first substrate 102a. The second tier 602b includes a 3D capacitor array 702 comprising a plurality of 3D capacitors 114 arranged within a second ILD structure 110b on a second substrate 102b.

The first tier 602a is coupled to the second tier 602b by a bonding region 708 having a bonding interface that includes conductive regions and dielectric regions. In some embodiments, the bonding region 708 includes bond connects 712 and bond links 714 disposed within an insulating layer 710. The bond connects 712 and the bond links 714 connect the plurality of 3D capacitors 144 to the first tier 602a. The bond connects 712 are directly above the plurality of 3D capacitors 114 and are directly connected to the bond links 714.

FIG. 8D illustrates a cross-sectional view of some additional embodiments of a multi-dimensional integrated chip structure 806 having three-dimensional capacitor arranged within a second tier.

The multi-dimensional integrated chip structure 806 comprises a first tier 602a stacked onto a second tier 602b. In some embodiments, the first tier 602a is coupled to the second tier 602b by a bonding region 708 having a bonding interface that includes conductive regions and dielectric regions.

The first tier 602a includes a pixel array 106 having a plurality of pixel regions 106a-106c within a first substrate 102a. The second tier 602b includes a 3D capacitor array 702 comprising a plurality of 3D capacitors 114 arranged within a second ILD structure 110b on a second substrate 102b. The second tier 602b may further include a second pixel array 808 having a plurality of pixel regions within the second substrate 102b. In some embodiments, the pixel array 106 comprises image sensing elements 104 that are configured to detect incident radiation having a first range of frequencies (e.g., within an infrared region of the electromagnetic spectrum) and the second pixel array 808 comprises image sensing elements 810 that are configured to detect incident radiation having a second range of frequencies (e.g., within a near infrared region of the electromagnetic spectrum) that is different than the first range of frequencies. Although the 3D capacitor array 702 is shown as being directly above the second pixel array 808 in FIG. 8D, it will be appreciated that in alternative embodiments, the 3D capacitor array 702 and/or interconnects may be arranged to be laterally outside of image sensing elements 810 within the second pixel array 808, so as to increase incident radiation reaching the second pixel array 808.

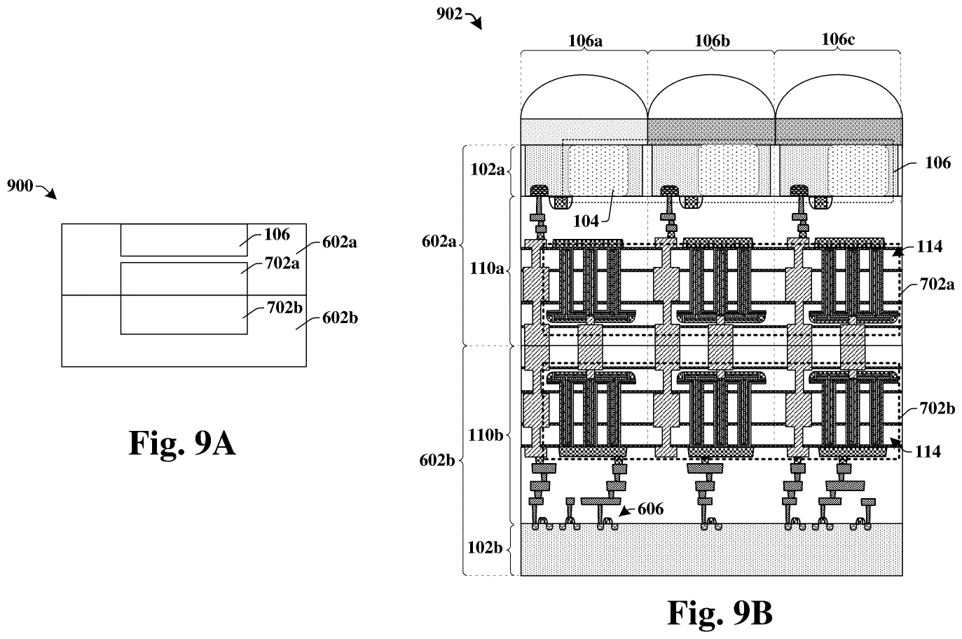

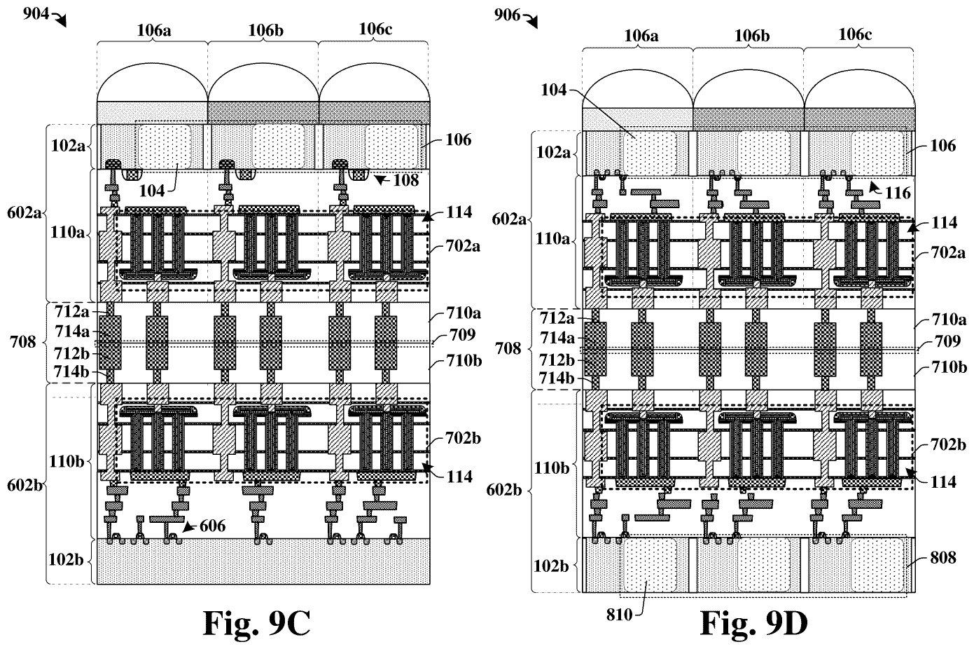

FIG. 9A illustrates a block diagram of a multi-dimensional integrated chip structure 900 having 3D capacitor arrays arranged within a first tier and a second tier.

The multi-dimensional integrated chip structure 900 comprises a first tier 602a and a second tier 602b stacked onto the first tier 602a. The first tier 602a includes a pixel array 106 comprising a plurality of image sensing elements (e.g., photodiodes) within a plurality of pixel regions. The first tier 602a further includes a first 3D capacitor array 702a comprising a plurality of 3D capacitors. The second tier 602b includes a second 3D capacitor array 702b comprising a plurality of 3D capacitors.

FIG. 9B illustrates a cross-sectional view of a multi-dimensional integrated chip structure 902 having three-dimensional capacitors arranged within a first tier and a second tier.

The multi-dimensional integrated chip structure 902 comprises a first tier 602a stacked onto a second tier 602b. The first tier 602a includes a plurality of image sensing elements 104 disposed within the first substrate 102a in a pixel array 106 having a plurality of pixel regions 106a-106c. A first ILD structure 110a is disposed on a first substrate 102a. The second tier 602b includes a second ILD structure 110b disposed on a second substrate 102b.

A first 3D capacitor array 702a is disposed within the first ILD structure 110a. The first 3D capacitor array 702a comprises a plurality of 3D capacitors 114 respectively disposed within one of the plurality of pixel regions 106a-106c. The plurality of 3D capacitors 114 are arranged between a top and a bottom of the first ILD structure 110a. A second 3D capacitor array 702b is disposed within the second ILD structure 110b. The second 3D capacitor array 702b comprises a plurality of 3D capacitors 114 respectively disposed within one of the plurality of pixel regions 106a-106c. The plurality of 3D capacitors 114 are arranged between a top and a bottom of the second ILD structure 110b. In some embodiments, the second tier 602b may further comprise one or more pixel support devices 606 (e.g., for a CIS circuit, a CDS circuit, a global shutter circuit, a LOFIC circuit, etc.).

FIG. 9C illustrates a cross-sectional view of some additional embodiments of a multi-dimensional integrated chip structure 904 having three-dimensional capacitors arranged within a first tier and a second tier.

The multi-dimensional integrated chip structure 904 comprises a first tier 602a coupled to a second tier 602b by a bonding region 708 having a bonding interface that includes conductive regions and dielectric regions. The first tier 602a includes a pixel array 106 having a plurality of pixel regions 106a-106c within a first substrate 102a. A first 3D capacitor array 702a is disposed within a first ILD structure 110a disposed on the first substrate 102a. The second tier 602b includes a second 3D capacitor array 702b comprising a plurality of 3D capacitors 114 arranged within a second ILD structure 110b on a second substrate 102b.

FIG. 9D illustrates a cross-sectional view of some additional embodiments of a multi-dimensional integrated chip structure 906 having three-dimensional capacitors arranged within a first tier and a second tier.

The multi-dimensional integrated chip structure 906 comprises a first tier 602a coupled to a second tier 602b by a bonding region 708 having a bonding interface that includes conductive regions and dielectric regions. The first tier 602a includes a pixel array 106 having a plurality of pixel regions 106a-106c within a first substrate 102a. A first 3D capacitor array 702a is disposed within a first ILD structure 110a disposed on the first substrate 102a. The second tier 602b includes a second 3D capacitor array 702 comprising a plurality of 3D capacitors 114 arranged within a second ILD structure 110b on a second substrate 102b. The second tier 602b may further include a second pixel array 808 having a plurality of pixel regions within the second substrate 102b. In some embodiments, the pixel array 106 comprises image sensing elements 104 that are configured to detect incident radiation having a first range of frequencies (e.g., within an infrared region of the electromagnetic spectrum) and the second pixel array 808 comprises image sensing elements 810 that are configured to detect incident radiation having a second range of frequencies (e.g., within a near infrared region of the electromagnetic spectrum).

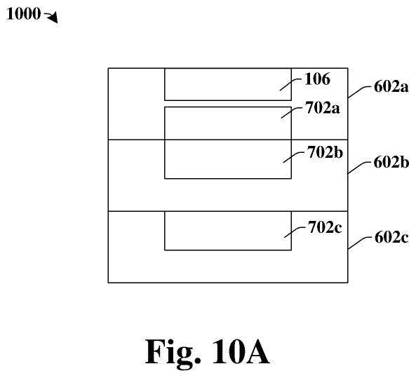

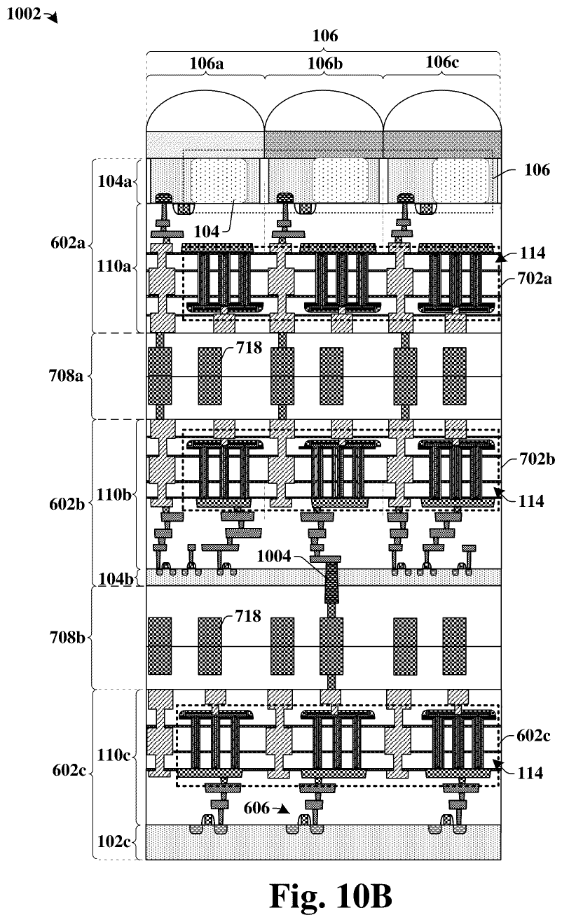

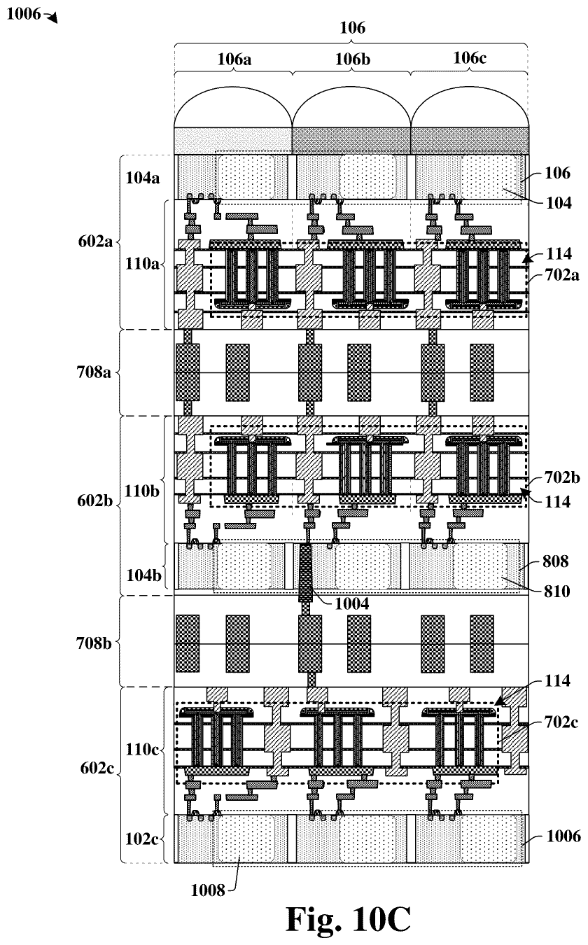

FIG. 10A illustrates a block diagram of a multi-dimensional integrated chip structure 1000 having 3D capacitor arrays arranged within a first tier, a second tier, and a third tier.

The multi-dimensional integrated chip structure 1000 comprises a first tier 602a, a second tier 602b stacked onto the first tier 602a, and a third tier 602c stacked onto the second tier 602b. The first tier 602a includes a pixel array 106 comprising a plurality of image sensing elements disposed within a plurality of pixel regions. The first tier 602a further includes a first 3D capacitor array 702a comprising a plurality of 3D capacitors. The second tier 602b includes a second 3D capacitor array 702b comprising a plurality of 3D capacitors. The third tier 602c includes a third 3D capacitor array 702c comprising a plurality of 3D capacitors.

FIG. 10B illustrates a cross-sectional view of a multi-dimensional integrated chip structure 1002 having 3D capacitors arranged within a first tier, a second tier, and a third tier.

The multi-dimensional integrated chip structure 1002 comprises a first tier 602a, a second tier 602b stacked onto the first tier 602a, and a third tier 602c stacked onto the second tier 602b. In some embodiments, the first tier 602a is bonded to the second tier 602b along a first bonding region 708a. In some embodiments, the second tier 602b is bonded to the third tier 602c along a second bonding region 708b. In some embodiments, a through substrate via (TSV) 1004 vertically extends through a second substrate 102b to connect the second tier 602b to the third tier 602c.

The first tier 602a includes a plurality of image sensing elements 104 disposed within the first substrate 102a in a pixel array 106 having a plurality of pixel regions 106a-106c. A first 3D capacitor array 702a is disposed within a first ILD structure 110a on the first substrate 102a. The first 3D capacitor array 702a comprises a plurality of 3D capacitors 114 respectively disposed within one of the plurality of pixel regions 106a-106c. The plurality of 3D capacitors 114 within the first 3D capacitor array 702a are arranged between a top and a bottom of the first ILD structure 110a.

The second tier 602b includes a second ILD structure 110b disposed on a second substrate 102b. A second 3D capacitor array 702b is disposed within the second ILD structure 110b. The second 3D capacitor array 702b comprises a plurality of 3D capacitors 114 respectively disposed within one of the plurality of pixel regions 106a-106c. The plurality of 3D capacitors 114 within the second 3D capacitor array 702b are arranged between a top and a bottom of the second ILD structure 110b.

The third tier 602c includes a third interconnect structure 110c disposed on a third substrate 102c. A third 3D capacitor array 702c is disposed within the third interconnect structure 110c. The third 3D capacitor array 702c comprises a plurality of 3D capacitors 114 respectively disposed within one of the plurality of pixel regions 106a-106c. The plurality of 3D capacitors 114 within the third 3D capacitor array 702c are arranged between a top and a bottom of the third interconnect structure 110c.

FIG. 10C illustrates a cross-sectional view of a multi-dimensional integrated chip structure 1006 having 3D capacitors arranged within a first tier, a second tier, and a third tier.

The multi-dimensional integrated chip structure 1006 comprises a first tier 602a, a second tier 602b stacked onto the first tier 602a, and a third tier 602c stacked onto the second tier 602b. The first tier 602a includes a plurality of image sensing elements 104 disposed within the first substrate 102a in a pixel array 106 having a plurality of pixel regions 106a-106c. A first 3D capacitor array 702a is disposed within a first ILD structure 110a on the first substrate 102a. The second tier 602b includes a plurality of image sensing elements 810 disposed within a second substrate 102b in a second pixel array 808 having a plurality of pixel regions within the second substrate 102b. A second 3D capacitor array 702b is disposed within a second ILD structure 110b on the second substrate 102b. The third tier 602c includes a plurality of image sensing elements 1008 disposed within a third substrate 102c in a third pixel array 1006 having a plurality of pixel regions within the third substrate 102c. A third 3D capacitor array 702c is disposed within a third interconnect structure 110c on the third substrate 102c.

In some embodiments, the image sensing elements 104 are configured to detect incident radiation having a first range of frequencies (e.g., within an infrared region of the electromagnetic spectrum), the image sensing elements 810 are configured to detect incident radiation having a second range of frequencies that is different than the first range of frequencies (e.g., within a near infrared region of the electromagnetic spectrum), and the image sensing elements 810 are configured to detect incident radiation having a third range of frequencies that is different than the first and second range of frequencies (e.g., within a far infrared region of the electromagnetic spectrum).

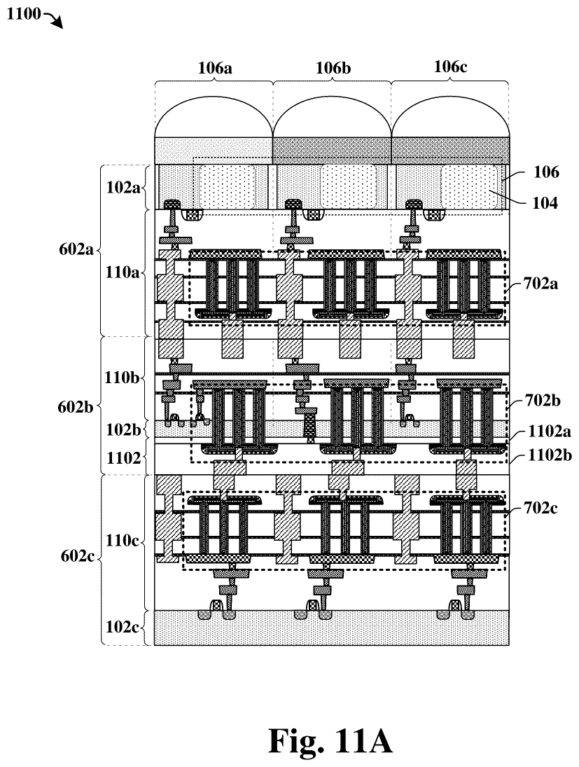

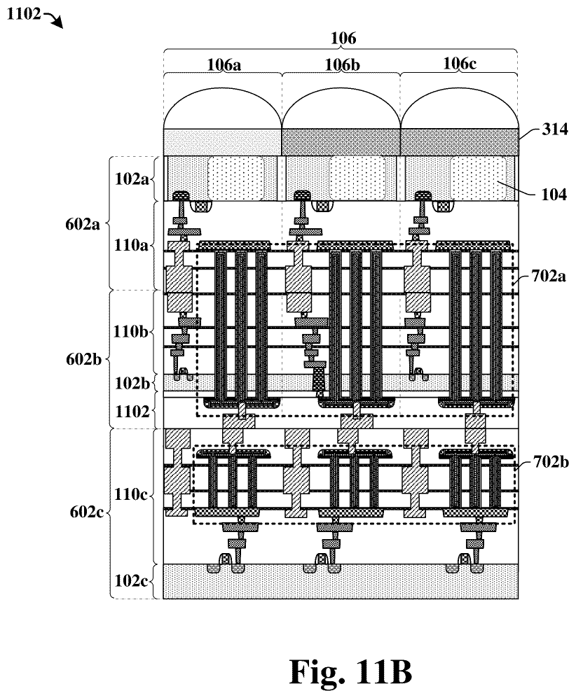

FIG. 11A illustrates a block diagram of a multi-dimensional integrated chip structure 1100 having 3D capacitor arrays arranged within a first tier, a second tier, and a third tier.

The multi-dimensional integrated chip structure 1100 comprises a first tier 602a, a second tier 602b stacked onto the first tier 602a, and a third tier 602c stacked onto the second tier 602b. The first tier 602a includes a plurality of image sensing elements 104 disposed within the first substrate 102a in a pixel array 106 having a plurality of pixel regions 106a-106c. A first 3D capacitor array 702a comprises a plurality of 3D capacitors 114 disposed within a first ILD structure 110a on the first substrate 102a. The second tier 602b includes a second 3D capacitor array 702b. The second 3D capacitor array 702b comprises a plurality of 3D capacitors 114 disposed within a second ILD structure 110b on a second substrate 102b. The plurality of 3D capacitors 114 within the second 3D capacitor array 702b are configured to extend thorough the second substrate 102b. In some embodiments, the plurality of 3D capacitors 114 within the second 3D capacitor array 702b are formed within a back-side interconnect structure 1102 arranged on a back-side of the second substrate 102b. In some embodiments, the back-side interconnect structure 1102 may include multiple back-side ILD layers 1102a-1102b. The third tier 602c includes a third 3D capacitor array 702c is disposed within a third interconnect structure 110c on the third substrate 102c.

FIG. 11B illustrates a block diagram of a multi-dimensional integrated chip structure 1102 having 3D capacitor arrays arranged within a first tier, a second tier, and a third tier.

The multi-dimensional integrated chip structure 1102 comprises a first tier 602a, a second tier 602b stacked onto the first tier 602a, and a third tier 602c stacked onto the second tier 602b. The first tier 602a includes a plurality of image sensing elements 104 disposed within the first substrate 102a in a pixel array 106 having a plurality of pixel regions 106a-106c. A first 3D capacitor array 702a comprises a plurality of 3D capacitors 114 disposed within a first ILD structure 110a on the first substrate 102a and within a second ILD structure 110b on a second substrate 102b. The plurality of 3D capacitors 114 within the first 3D capacitor array 702a are configured to extend thorough the second substrate 102b. The third tier 602c includes a second 3D capacitor array 702b disposed within a third interconnect structure 110c on the third substrate 102c.

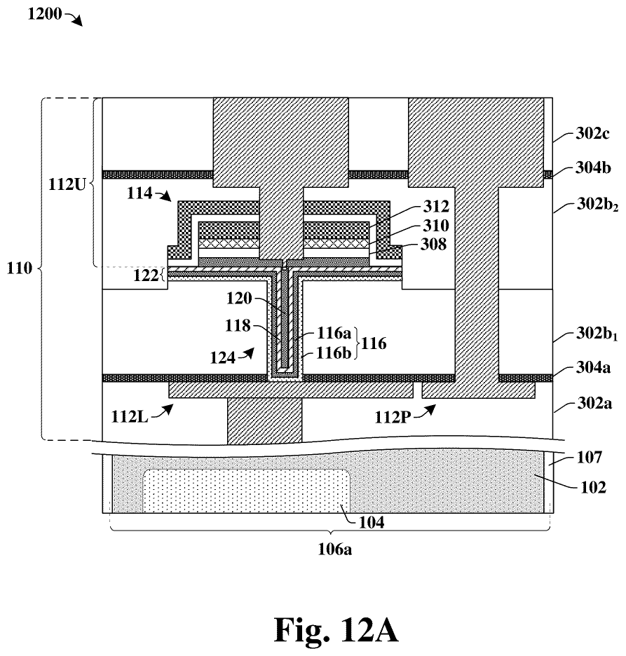

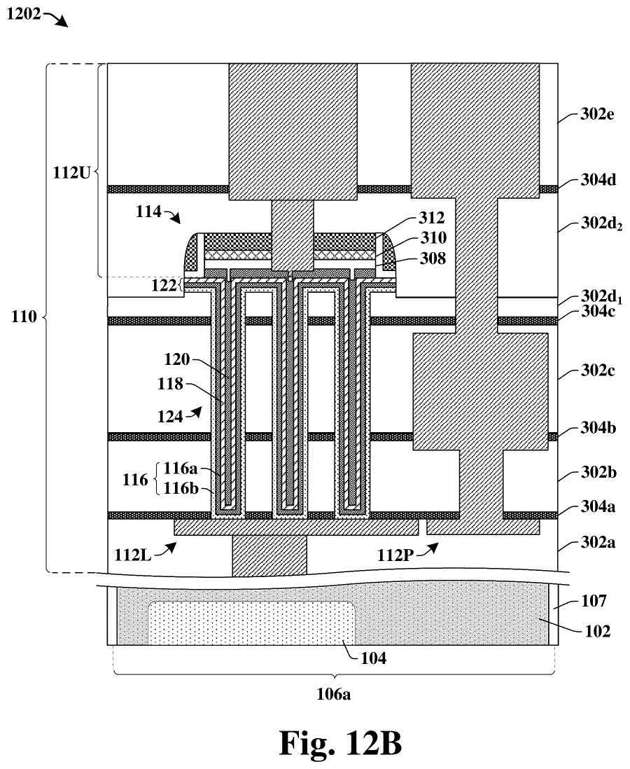

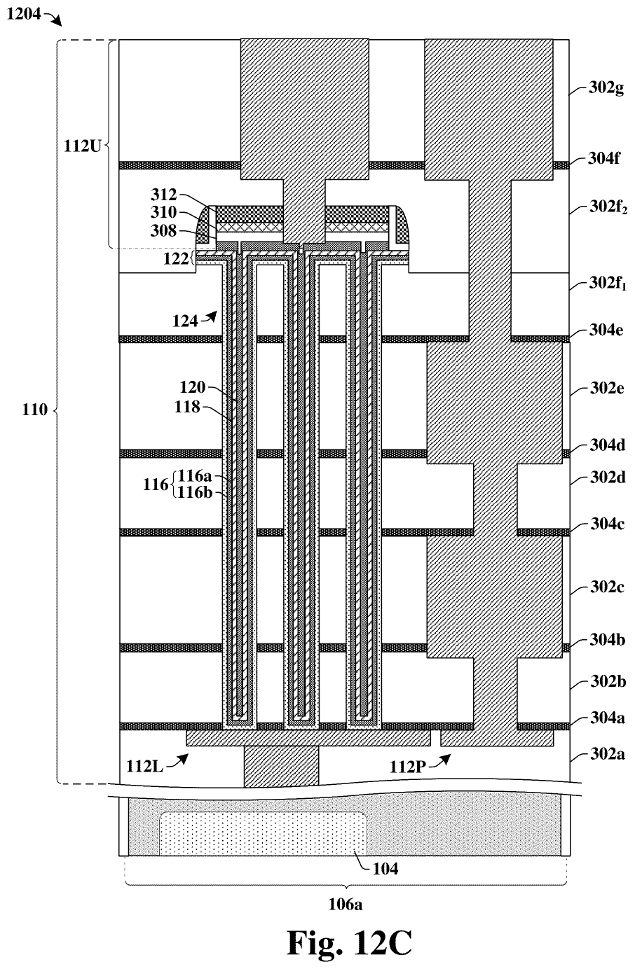

In various embodiments, the disclosed 3D capacitors may have different heights. The different heights of the disclosed 3D capacitors allow for the 3D capacitors to provide different capacitance values while still having a small enough footprint to be entirely contained within a pixel region of a pixel array. The use of 3D capacitors having different heights allows for different 3D capacitors to be used for different applications (e.g., for pixel sensor, pixel storage, and CDS (Correlated double sampling) circuits, or the like). FIGS. 12A-12C illustrate some embodiments of disclosed 3D capacitors having different heights.

FIG. 12A illustrates a cross-sectional view of an integrated chip structure 1200 having a 3D capacitor with a first height.

The integrated chip structure 1200 comprises an ILD structure 110 disposed over a substrate 102. The ILD structure 110 includes a first ILD layer 302a disposed over a substrate 102. A lower interconnect structure 112L is arranged within the first ILD layer 302a. A first etch stop layer (ESL) 304a is arranged over the first ILD layer 302a. A lower second ILD layer 302b₁ is over the first ESL 304a. A 3D capacitor 114 is arranged over the lower second ILD layer 302b₁. The 3D capacitor 114 comprises a base region 122 and one or more fingers 124. The one or more fingers 124 vertically extends outward from a bottom of the base region 122 and through the lower second ILD layer 302b₁ to contact the lower interconnect structure 112L.

An upper second ILD layer 302b₂ is disposed over the lower second ILD layer 302b₁ and the 3D capacitor 114. In some embodiments, the upper second ILD layer 302b₂ is disposed along sidewalls of lower second ILD layer 302b₁. A second ESL 304b is arranged over the upper second ILD layer 302b₂ and a third ILD layer 302c is arranged over the second ESL 304b. An upper interconnect structure 112U extends through the third ILD layer 302c, the second ESL 304b, and the upper second ILD layer 302b₂ to contact the 3D capacitor 114. A peripheral interconnect structure 112P may be arranged within the ILD structure 110 and be laterally separated from the 3D capacitor 114 by the lower second ILD layer 302b₁ and the upper second ILD layer 302b₂.

FIG. 12B illustrates a cross-sectional view of an integrated chip structure 1202 having a 3D capacitor with a second height.

The integrated chip structure 1202 comprises an ILD structure 110 disposed over a substrate 102. The ILD structure 110 includes a first ILD layer 302a disposed over a substrate 102. A lower interconnect structure 112L is arranged within the first ILD layer 302a. A first ESL 304a is arranged over the first ILD layer 302a, a second ILD layer 302b is over the first ESL 304a, a second ESL 304b is over the second ILD layer 302b, a third ILD layer 302c is over the second ESL 304b, a third ESL 304c is over the third ILD layer 302c, and a lower fourth ILD layer 302d₁ is over the third ESL 304c.

A 3D capacitor 114 is disposed within the ILD structure 110. The 3D capacitor 114 comprises a base region 122 and one or more fingers 124. The base region 122 rests on an upper surface of the lower fourth ILD layer 302d₁. The one or more fingers 124 vertically extends outward from a bottom of the base region 122 and through the first ESL 304a, the second ILD layer 302b, the second ESL 304b, the third ILD layer 302c, the third ESL 304c, and the lower fourth ILD layer 302d₁ to contact the lower interconnect structure 112L.

An upper fourth ILD layer 302d₂ is disposed over the lower fourth ILD layer 302d₁ and the 3D capacitor 114. In some embodiments, the upper fourth ILD layer 302d₂ is disposed along sidewalls of the lower fourth ILD layer 302d₁. A fourth ESL 304d is arranged over the upper fourth ILD layer 302d₂ and a fifth ILD layer 302e is arranged over the fourth ESL 304d. An upper interconnect structure 112U extends through the fifth ILD layer 302e, the fourth ESL 304d, and the upper fourth ILD layer 302d₂ to contact the 3D capacitor 114. A peripheral interconnect structure 112P may be arranged within the ILD structure 110 and be laterally separated from the 3D capacitor 114 by the lower fourth ILD layer 302d₁ and the upper fourth ILD layer 302d₂.

FIG. 12C illustrates a cross-sectional view of an integrated chip structure 1204 having a 3D capacitor with a third height.

The integrated chip structure 1204 comprises an ILD structure 110 disposed over a substrate 102. The ILD structure 110 includes a first ILD layer 302a disposed over a substrate 102. A lower interconnect structure 112L is arranged within the first ILD layer 302a. A first ESL 304a is arranged over the first ILD layer 302a, a second ILD layer 302b is over the first ESL 304a, a second ESL 304b is over the second ILD layer 302b, a third ILD layer 302c is over the second ESL 304b, a third ESL 304c is over the third ILD layer 302c, and a fourth ILD layer 302d is over the third ESL 304c, a fourth ESL 304d is over the fourth ILD layer 302d, a fifth ILD layer 302e is over the fourth ESL 304d, a fifth ESL 304e is over the fifth ILD layer 302e, and a lower sixth ILD layer 302f₁ is over the fifth ESL 304e.

A 3D capacitor 114 is disposed within the ILD structure 110. The 3D capacitor 114 comprises a base region 122 and one or more fingers 124. The base region 122 rests on an upper surface of the lower sixth ILD layer 302f₁. The one or more fingers 124 vertically extends outward from a bottom of the base region 122 and through the first ESL 304a, the second ILD layer 302b, the second ESL 304b, the third ILD layer 302c, the third ESL 304c, the fourth ILD layer 302d, the fourth ESL 304d, the fifth ILD layer 302e, the fifth ESL 304e, and the lower sixth ILD layer 302f₁ to contact the lower interconnect structure 112L.

An upper sixth ILD layer 302f₂ is disposed over the lower sixth ILD layer 302f₁ and the 3D capacitor 114. In some embodiments, the upper sixth ILD layer 302f₂ is disposed along sidewalls of the lower sixth ILD layer 302f₁. A sixth ESL 304f is arranged over the upper sixth ILD layer 302f₂ and a seventh ILD layer 302g is arranged over the sixth ESL 304f. An upper interconnect structure 112U extends through the seventh ILD layer 302g, the sixth ESL 304f, and the upper sixth ILD layer 302f₂ to contact the 3D capacitor 114. A peripheral interconnect structure 112P may be arranged within the ILD structure 110 and be laterally separated from the 3D capacitor 114 by the lower sixth ILD layer 302f₁ and the upper sixth ILD layer 302f₂.

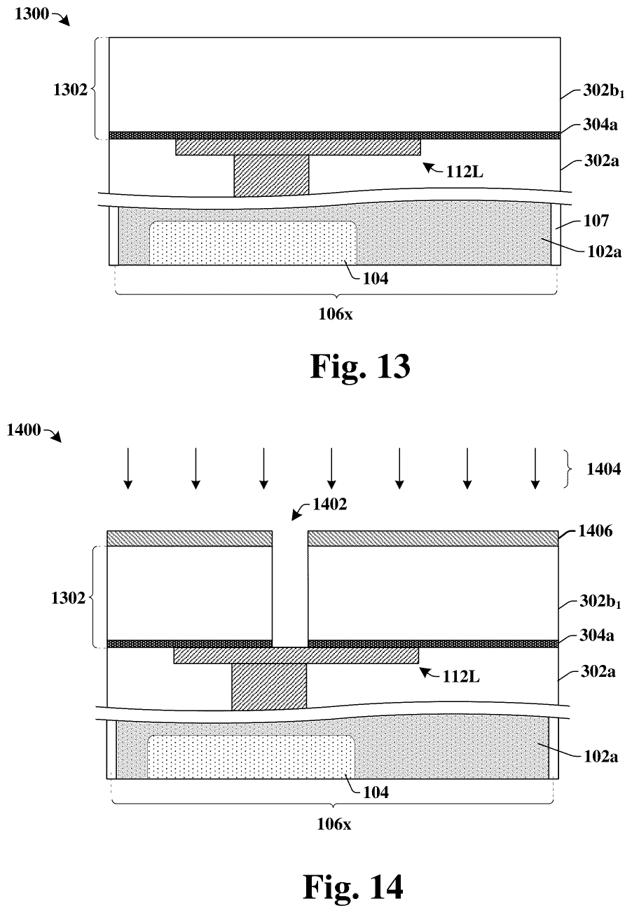

FIGS. 13-20 illustrate cross-sectional views 1300-2000 of some embodiments of a method of forming a three-dimensional capacitor within a pixel region of an image sensor integrated chip. Although FIGS. 13-20 are described in relation to a method, it will be appreciated that the structures disclosed in the method are not limited to the method, but instead may stand alone as structures independent of the method.

As shown in cross-sectional view 1300 of FIG. 13, a first substrate 102a is provided. In various embodiments, the first substrate 102a may be any type of semiconductor body (e.g., silicon, SiGe, etc.), such as a semiconductor wafer and/or one or more die on a wafer, as well as any other type of semiconductor and/or epitaxial layers, associated therewith.

The first substrate 102a comprises a plurality of pixel regions 106x arranged within a pixel array. In some embodiments, one or more isolation structures 107 may be formed within the first substrate 102a along boundaries of the plurality of pixel regions 106x. In some embodiments, the plurality of pixel regions 106x may be comprised within a pixel array within the first substrate 102a. In some embodiments, the plurality of image sensing elements 104 may comprise a photodiode formed by implanting one or more dopant species into a front-side of the first substrate 102a. For example, the plurality of image sensing elements 104 may be formed by selectively performing a first implantation process (e.g., according to a first masking layer) to form a first region having a first doping type (e.g., n-type), and subsequently performing a second implantation process to form a second region abutting the first region and having a second doping type (e.g., p-type) different than the first doping type. In other embodiments (not shown), the first substrate 102a may be devoid of image sensing elements. In some such embodiments, the one or more pixel support devices (e.g., reset transistors, source-follower transistors, row-select transistors, etc.) may be formed onto the first substrate 102a.

A lower interconnect structure 112L is formed within a first ILD layer 302a formed over the first substrate 102a. In some embodiments, the lower interconnect structure 112L may be formed using a damascene process (e.g., a single damascene process and/or a dual damascene process). For example, the damascene process may be performed by forming the first ILD layer 302a on the first substrate 104a, etching the first ILD layer 302a to form a via hole and/or a trench, filling the via hole and/or trench with a conductive material, and performing a planarization process (e.g., a chemical mechanical planarization process) to remove excess of the conductive material from over the first ILD layer 302a. In some embodiments, the first ILD layer 302a may be formed by a deposition technique (e.g., PVD, CVD, PE-CVD, ALD, etc.) and the conductive material may be formed using a deposition process and/or a plating process (e.g., electroplating, electro-less plating, etc.). In various embodiments, the conductive material may comprise tungsten, copper, aluminum, and/or the like.

A lower ILD structure 1302 is formed over the first ILD layer 302a. In some embodiments, the lower ILD structure 1302 may be formed by forming a first etch stop layer (ESL) 304a over the first ILD layer 302a and a lower second ILD layer 302b₁ over the first ESL 304a. In some embodiments, the first ESL 304a and the lower second ILD layer 302b₁ may be formed by deposition techniques (e.g., PVD, CVD, PE-CVD, ALD, etc.). In some embodiments, the first ESL 304a may comprise a nitride (e.g., silicon nitride, silicon oxynitride), a carbide (e.g., silicon carbide), and/or the like. In some embodiments, the lower second ILD layer 302b₁ may comprise an oxide (e.g., silicon dioxide), a nitride (e.g., silicon nitride, silicon oxynitride), a carbide (e.g., silicon carbide), borosilicate glass (BSG), phosphoric silicate glass (PSG), borophosphosilicate glass (BPSG), a low-k oxide (e.g., a carbon doped oxide, SiCOH), and/or the like.

As shown in cross-sectional view 1400 of FIG. 14, the lower ILD structure 1302 is selectively patterned by way of an etching process to form an opening 1402 that vertically extends through the lower second ILD layer 302b₁ and the first ESL 304a to expose the lower interconnect structure 112L. In some embodiments, the etching process may expose the lower second ILD layer 302b₁ to one or more etchants 1404 according to a mask 1406. In some embodiments, the one or more etchants 1404 may comprise a dry etchant having an etching chemistry comprising one or more of oxygen (O₂), nitrogen (N₂), hydrogen (H₂), argon (Ar), a fluorine species (e.g., CF₄, CHF₃, C₄F₈, etc.), and/or the like. In some embodiments, the mask 1406 may comprise a photoresist, a hard mask, or the like.

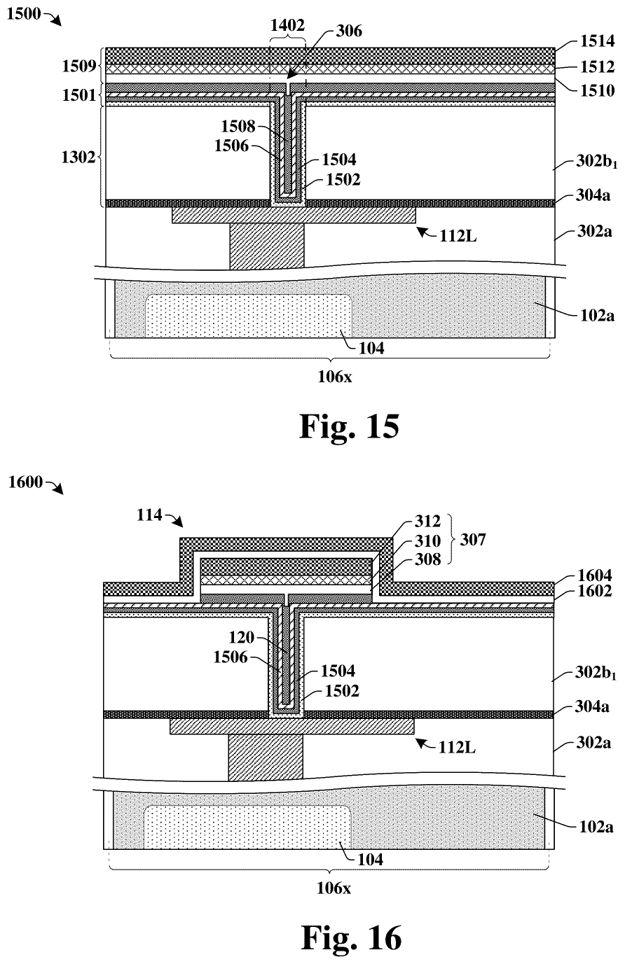

As shown in cross-sectional view 1500 of FIG. 15, a capacitor stack 1501 is formed within the opening 1402 and over a top of the lower ILD structure 1302. In some embodiments, the capacitor stack 1501 may be formed by forming a capacitor barrier layer 1502 within the opening 1402 and over the lower second ILD layer 302b₁. The capacitor barrier layer 1502 lines sidewalls of the first ESL 304a and the lower second ILD layer 302b₁. A first capacitor electrode layer 1504 is formed over the capacitor barrier layer 1502. The first capacitor electrode layer 1504 lines sidewalls and upper surfaces of the capacitor barrier layer 1502. A capacitor dielectric layer 1506 is formed over the first capacitor electrode layer 1504. The capacitor dielectric layer 1506 lines sidewalls and upper surfaces of the first capacitor electrode layer 1504. A second capacitor electrode layer 1508 is formed over the capacitor dielectric layer 1506. The second capacitor electrode layer 1508 lines sidewalls and upper surfaces of the capacitor dielectric layer 1506.

In some embodiments, the capacitor barrier layer 1502, the first capacitor electrode layer 1504, the capacitor dielectric layer 1506, and the second capacitor electrode layer 1508 may respectively be formed by separate deposition techniques (e.g., PVD, CVD, PE-CVD, ALD, etc.). In some embodiments, the capacitor barrier layer 1502 may comprise or be tantalum, tantalum nitride, titanium, titanium nitride, and/or the like. In some embodiments, the first capacitor electrode layer 1504 may comprise or be a metal such as titanium, or the like. In some embodiments, the capacitor dielectric layer 1506 may comprise or be a high-k dielectric material such as silicon nitride (SiNₓ), tantalum oxide (Ta₂O₅), aluminum oxide (Al₂O₃), zirconium oxide (ZrO₂), hafnium oxide (HfO₂), hafnium aluminum oxide (HfAlO), zirconium aluminum oxide (ZrAlO), and/or the like. In some embodiments, the capacitor dielectric layer 1506 may comprise or be a single high-k dielectric material or a stack of multiple high-k dielectric materials. In some embodiments, the second capacitor electrode layer 1508 may comprise or be a metal such as titanium, or the like. In some embodiments, the second capacitor electrode layer 1508 is formed to have one or more interior surfaces that form a recess 306 over a bottom of the second capacitor electrode layer 1508.

In some embodiments, a capacitor capping stack 1509 may be formed by further forming a first upper capacitor dielectric layer 1510 over the second capacitor electrode layer 1508, a second upper capacitor dielectric layer 1512 over the first upper capacitor dielectric layer 1510, and a third upper capacitor dielectric layer 1514 over the second upper capacitor dielectric layer 1512.

In some embodiments, the first upper capacitor dielectric layer 1510, the second upper capacitor dielectric layer 1512, and the third upper capacitor dielectric layer 1514 may respectively be formed by separate deposition techniques (e.g., PVD, CVD, PE-CVD, ALD, etc.). In some embodiments, the first upper capacitor dielectric layer 1510 may comprise or be an oxide (e.g., silicon oxide, silicon dioxide, etc.) or the like. In some embodiments, the second upper capacitor dielectric layer 1512 may comprise or be an oxide (e.g., silicon oxide, silicon dioxide, etc.), a nitride (e.g., silicon oxynitride, etc.), or the like. In some embodiments, the third upper capacitor dielectric layer 1514 may comprise or be a nitride (e.g., silicon nitride, etc.) or the like.

As shown in cross-sectional view 1600 of FIG. 16, the capacitor capping stack (e.g., 1509 of FIG. 15) is patterned according to an etching process to form a capacitor cap 307. The etching process removes parts of the first upper capacitor dielectric layer to form a first upper dielectric 308, parts of the second upper capacitor dielectric layer to form a second upper dielectric 310, and parts of the third upper capacitor dielectric layer to form a third upper dielectric 312. In some embodiments, the etching process further removes parts of the second capacitor electrode layer to form a second electrode 120.

After patterning the capacitor capping stack to form the capacitor cap 307, a first hard mask 1602 is formed onto the capacitor dielectric layer 1506 and along sidewalls and an upper surface of the capacitor cap 307. A second hard mask 1604 is formed along sidewalls and an upper surface of the first hard mask 1602. In some embodiments, the first hard mask 1602 and the second hard mask 1604 may respectively be formed by separate deposition techniques (e.g., PVD, CVD, PE-CVD, ALD, etc.). In some embodiments, the first hard mask 1602 may comprise or be an oxide (e.g., silicon oxide, silicon dioxide, etc.) or the like. In some embodiments, the second hard mask 1604 may comprise or be a nitride (e.g., silicon nitride, etc.) or the like.

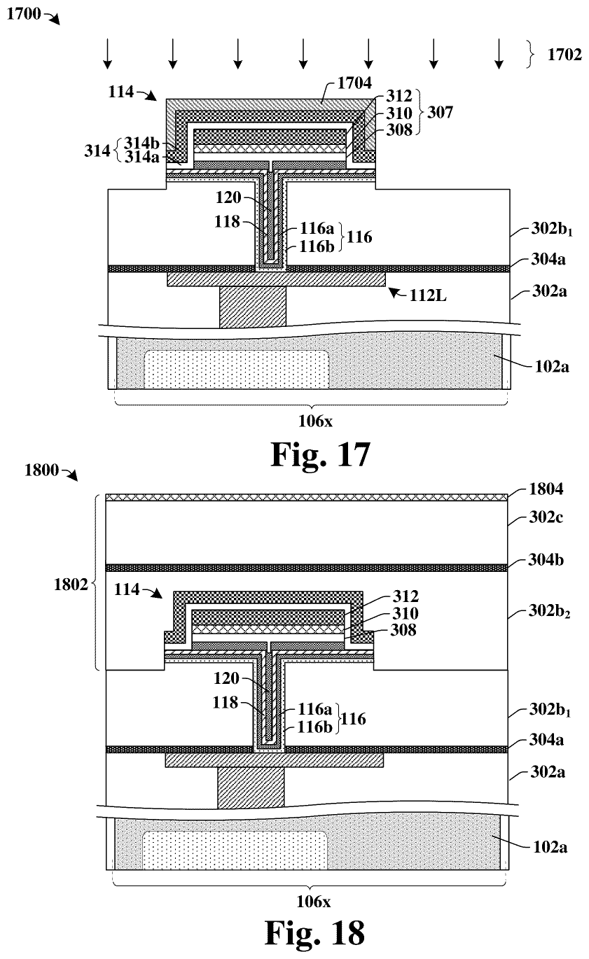

As shown in cross-sectional view 1700 of FIG. 17, the first hard mask (e.g., 1602 of FIG. 16) and the second hard mask (e.g., 1604 of FIG. 16) are etched to form one or more sidewall spacers 314. In some embodiments, the one or more sidewall spacers 314 may continuously extend from a first side of the capacitor cap 307 to an opposing second side of the capacitor cap 307. In some embodiments, the first hard mask and the second hard mask may be etched by selectively exposing the first hard mask and the second hard mask to one or more etchants 1702 according to a mask 1704.

In some embodiments, the one or more etchants 1702 may further etch the capacitor dielectric layer to form a capacitor dielectric 118, the first capacitor electrode layer to form a lower capacitor metal 116a, and the capacitor barrier layer to form a capacitor barrier 116b. In some embodiments, the etchants may also etch the lower second ILD layer 302b₁ so as to recess a part of the lower second ILD layer 302b₁ a non-zero distance below an outermost sidewall of the capacitor barrier 116b.

As shown in cross-sectional view 1800 of FIG. 18, an upper ILD structure 1802 is formed onto the lower second ILD layer 302b₁ and over the 3D capacitor 114. In some embodiments, the upper ILD structure 1802 may be formed by forming an upper second ILD layer 302b₂ onto the lower second ILD layer 302b₁, forming a second ESL 304b on the upper second ILD layer 302b₂, and forming a third ILD layer 302c on the second ESL 304b. In some additional embodiments, a dielectric film 1804 (e.g., SiON or other dielectric) may be formed over the third ILD layer 302c. In some embodiments, the upper second ILD layer 302b₂, the second ESL 304b, and the third ILD layer 302c may be formed by separate deposition techniques (e.g., PVD, CVD, PE-CVD, ALD, etc.). In some embodiments, the upper second ILD layer 302b₂ and the third ILD layer 302c may comprise an oxide (e.g., silicon dioxide), a nitride (e.g., silicon nitride, silicon oxynitride), a carbide (e.g., silicon carbide), borosilicate glass (BSG), phosphoric silicate glass (PSG), borophosphosilicate glass (BPSG), a low-k oxide (e.g., a carbon doped oxide, SiCOH), and/or the like. In some embodiments, the second ESL 304b may comprise a nitride (e.g., silicon nitride, silicon oxynitride), a carbide (e.g., silicon carbide), and/or the like.

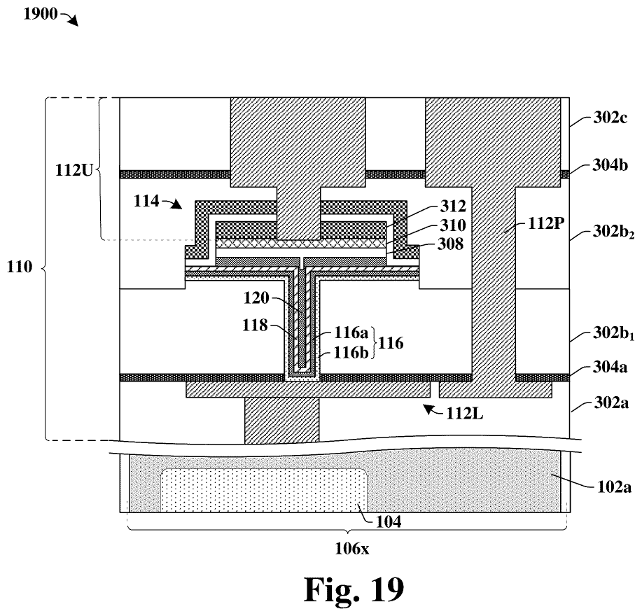

As shown in cross-sectional view 1900 of FIG. 19, an upper interconnect structure 112U is formed onto the 3D capacitor 114. The upper interconnect structure 112U is formed to extend vertically through the third ILD layer 302c, the second ESL 304b, and the upper second ILD layer 302b₂. In some embodiments, the upper interconnect structure 112U comprises a conductive via and/or a conductive wire. In some embodiments, the upper interconnect structure 112U may be formed using a damascene process (e.g., a single damascene process and/or a dual damascene process). In various embodiments, the upper interconnect structure 112U may comprise tungsten, copper, aluminum, copper, and/or the like. In some embodiments, the dielectric film (e.g., 1804 of FIG. 18) may be removed during a planarization process (e.g., a CMP process) used to form the upper interconnect structure 112U.

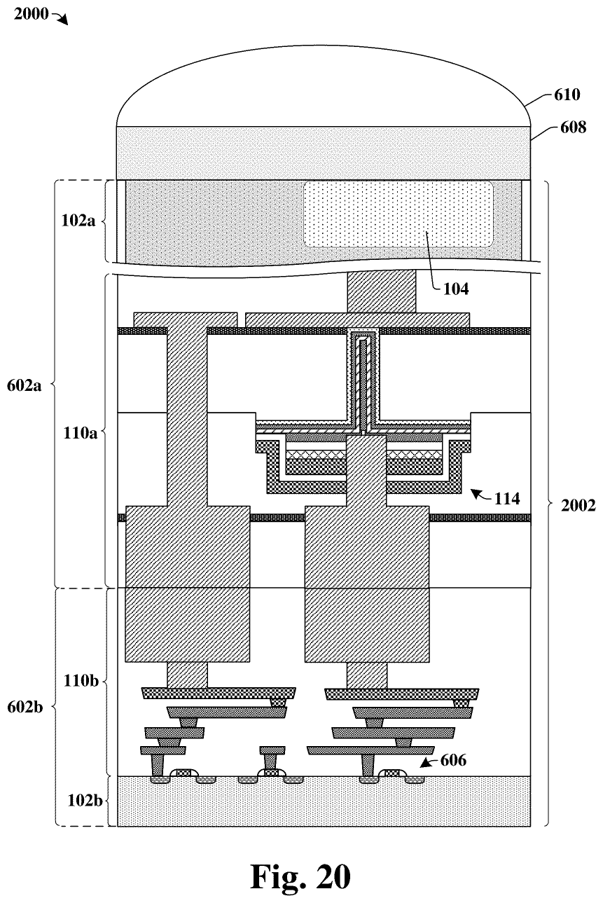

As shown in cross-sectional view 2000 of FIG. 20, in some additional embodiments, the first substrate 102a may be bonded to a second substrate 102b to form a multi-tiered integrated chip structure 2002. In some embodiments, the first substrate 102a may comprise a plurality of image sensing elements 104 and the second substrate 102b may comprise one or more pixel support devices 606 (e.g., reset transistors, source-follower transistors, row-select transistors, etc.). In other embodiments (not shown), the first substrate 102a may comprise one or more pixel support devices and the second substrate 102b may comprise a plurality of image sensing elements.

After bonding, the multi-tiered integrated chip structure 2002 may be singulated to form one or more integrated chip die (not shown). In some embodiments, multi-tiered integrated chip structure 2002 may be singulated by a dicing process that mounts the multi-tiered integrated chip structure 2002 onto a sticky surface of a piece of dicing tape. A wafer saw then cuts the wafer along scribe lines to separate the wafer into the one or more integrated chip die.

After singulation, a plurality of color filters 608 may be formed over the first substrate 102a. In some embodiments, the plurality of color filters 608 are formed by depositing (e.g., via CVD, PVD, ALD, sputtering, a spin-on process, etc.) a light filtering material(s) onto the first substrate 104a. The light filtering material(s) is a material that allows for the transmission of radiation (e.g., light) having a specific wavelength range, while blocking light of wavelengths outside of the specified range. Subsequently, in some embodiments, a planarization process (e.g., CMP) may be performed on the plurality of color filters 608 to planarize the upper surfaces of the plurality of color filters 608.

A plurality of micro-lenses 610 may be formed over the plurality of color filters 608. In some embodiments, the plurality of micro-lenses 610 may be formed by depositing a micro-lens material on the plurality of color filters 608 (e.g., via CVD, PVD, ALD, sputtering, a spin-on process, etc.). A micro-lens template (not shown) having a curved upper surface is patterned above the micro-lens material. In some embodiments, the micro-lens template may comprise a photoresist material exposed using a distributing exposing light dose (e.g., for a negative photoresist more light is exposed at a bottom of the curvature and less light is exposed at a top of the curvature), developed, and baked to form a rounding shape. The plurality of micro-lenses 610 are then formed by selectively etching the micro-lens material according to the micro-lens template.

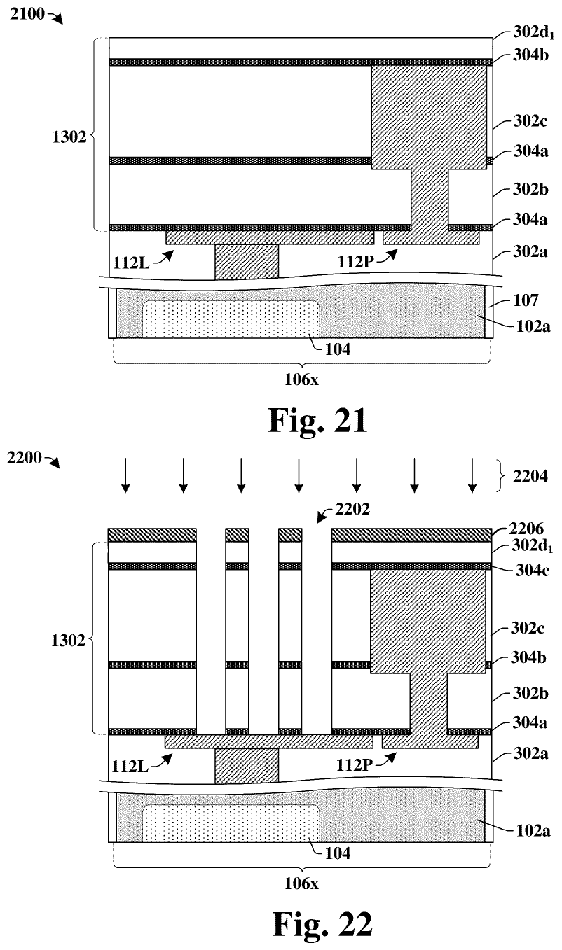

FIGS. 21-28 illustrate cross-sectional views 2100-2800 of some additional embodiments of a method of forming a three-dimensional capacitor within a pixel region of an image sensor integrated chip. Although FIGS. 21-28 are described in relation to a method, it will be appreciated that the structures disclosed in the method are not limited to the method, but instead may stand alone as structures independent of the method.

As shown in cross-sectional view 2100 of FIG. 21, a first substrate 102a is provided. The first substrate 102a comprises a plurality of pixel regions 106x arranged within a pixel array. In some embodiments, a plurality of image sensing elements 104 are formed within the plurality of pixel regions 106x. In other embodiments (not shown), the first substrate 102a may be devoid of image sensing elements. In some such embodiments, the one or more pixel support devices (e.g., reset transistors, source-follower transistors, row-select transistors, etc.) may be formed onto the first substrate 102a.

A lower interconnect structure 112L is formed within a first ILD layer 302a formed over the first substrate 102a. A lower ILD structure 1302 is formed over the first ILD layer 302a. In some embodiments, the lower ILD structure 1302 may be formed by forming a first ESL 304a over the first ILD layer 302a, a second ILD layer 302b over the first ESL 304a, a second ESL 304b over the second ILD layer 302b, a third ILD layer 302c over the second ESL 304b, a third ESL 304c over the third ILD layer 302c, and a lower fourth ILD layer 302d₁ over the third ESL 304c. A peripheral interconnect structure 112P is formed to extend through the first ILD layer 302a, the second ILD layer 302b, the second ESL 304b, and the third ILD layer 302c. In some embodiments, the lower interconnect structure 112L and the peripheral interconnect structure 112P may be formed using damascene processes (e.g., a single damascene process and/or a dual damascene process).

As shown in cross-sectional view 2200 of FIG. 22, the lower ILD structure 1302 is selectively patterned by way of an etching process to form an opening 2202 that vertically extends through the lower fourth ILD layer 302d₁, the third ESL 304c, the third ILD layer 302c, the second ESL 304b, the second ILD layer 302b, and the first ESL 304a. In some embodiments, the etching process may expose the lower fourth ILD layer 302d₁ to one or more etchants 2204 according to a mask 2206.

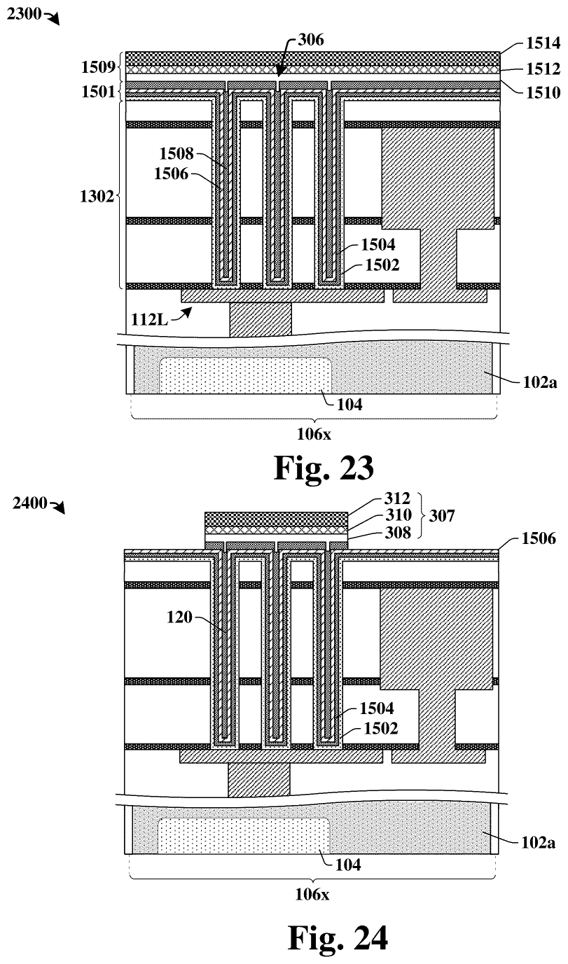

As shown in cross-sectional view 2300 of FIG. 23, a capacitor stack 1501 is formed within the opening 2202 and over a top of the lower ILD structure 1302. In some embodiments, the capacitor stack 1501 may comprise a capacitor barrier layer 1502, a first capacitor electrode layer 1504 formed over the capacitor barrier layer 1502, a capacitor dielectric layer 1506 formed over the first capacitor electrode layer 1504, and a second capacitor electrode layer 1508 formed over the capacitor dielectric layer 1506. In some embodiments, the second capacitor electrode layer 1508 is formed to have one or more interior surfaces that form recesses 306 over bottoms of the second capacitor electrode layer 1508.

In some embodiments, a capacitor capping stack 1509 may be formed by further forming a first upper capacitor dielectric layer 1510 over the second capacitor electrode layer 1508, a second upper capacitor dielectric layer 1512 over the first upper capacitor dielectric layer 1510, and a third upper capacitor dielectric layer 1514 over the second upper capacitor dielectric layer 1512.

As shown in cross-sectional view 2400 of FIG. 24, the capacitor capping stack (e.g., 1509 of FIG. 23) is patterned according to an etching process to form a capacitor cap 307. The etching process removes parts of the capacitor upper electrode layer to form a second electrode 120, parts of the first upper capacitor dielectric layer to form a first upper dielectric 308, parts of the second upper capacitor dielectric layer to form a second upper dielectric 310, and parts of the third upper capacitor dielectric layer to form a third upper dielectric 312.

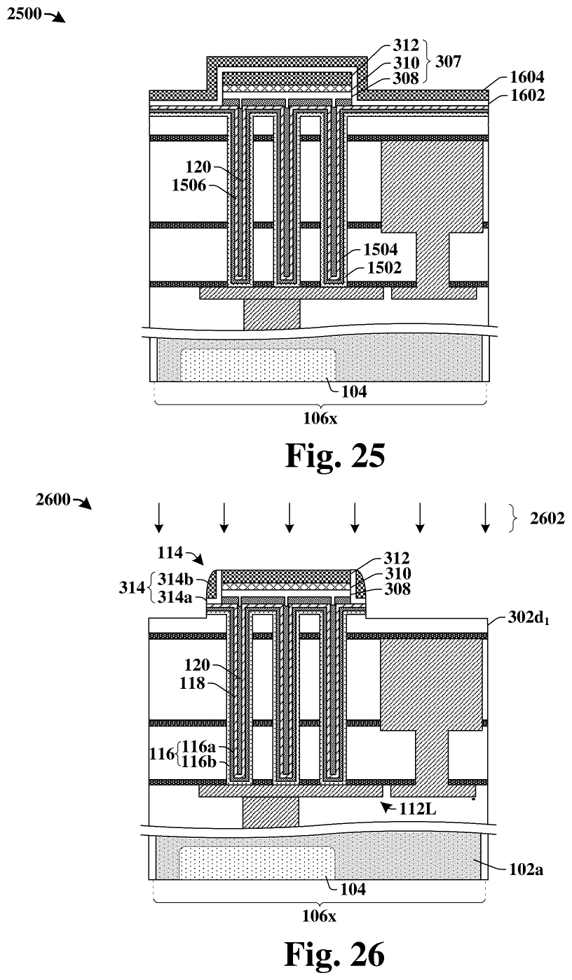

As shown in cross-sectional view 2500 of FIG. 25, a first hard mask 1602 is formed onto the capacitor dielectric layer 1506 and along sidewalls and an upper surface of the capacitor cap 307. A second hard mask 1604 is formed along sidewalls and an upper surface of the first hard mask 1602.

As shown in cross-sectional view 2600 of FIG. 26, the first hard mask (e.g., 1602 of FIG. 25) and the second hard mask (e.g., 1604 of FIG. 25) are etched using one or more etchants 2602. The one or more etchants 2602 remove horizontally extending segments of the first hard mask and the second hard mask to form one or more sidewall spacers 314 along opposing sides of the capacitor cap 307 and the second electrode 120. The one or more sidewall spacers 314 include a first dielectric spacer layer 314a and a second dielectric spacer layer 314b on the first dielectric spacer layer 314a.

The one or more etchants 2602 further etch the capacitor dielectric layer to form a capacitor dielectric 118, the first capacitor electrode layer to form a lower capacitor metal 116a, and the capacitor barrier layer to form a capacitor barrier 116b. In some embodiments, the etchants may also etch the second ILD layer 302b so as to recess a part of the lower fourth ILD layer 302d₁ a non-zero distance below an outermost sidewall of the capacitor barrier 116b.

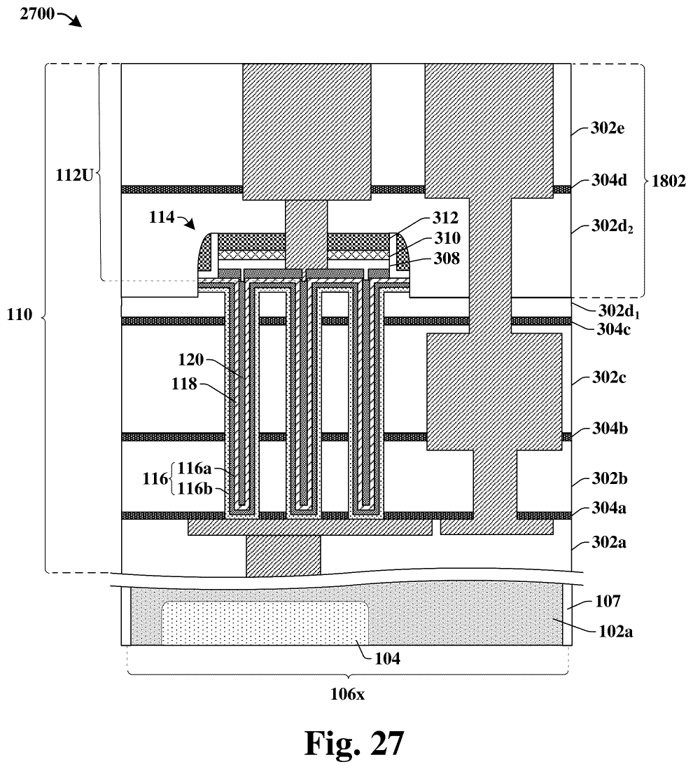

As shown in cross-sectional view 2700 of FIG. 27, an upper ILD structure 1802 is formed onto the lower fourth ILD layer 302d₁ and over the 3D capacitor 114. In some embodiments, the upper ILD structure 1802 is formed by forming an upper fourth ILD layer 302d₂ on the lower fourth ILD layer 302d₁, a fourth ESL 304d on the upper fourth ILD layer 302d₂, and a fifth ILD layer 302e on the fourth ESL 304d.

An upper interconnect structure 112U is formed onto the 3D capacitor 114. The upper interconnect structure 112U is formed to vertically extend through the fifth ILD layer 302e, the fourth ESL 304d, and the upper fourth ILD layer 302d₂. In some embodiments, the upper interconnect structure 112U comprises a conductive via and a conductive wire.

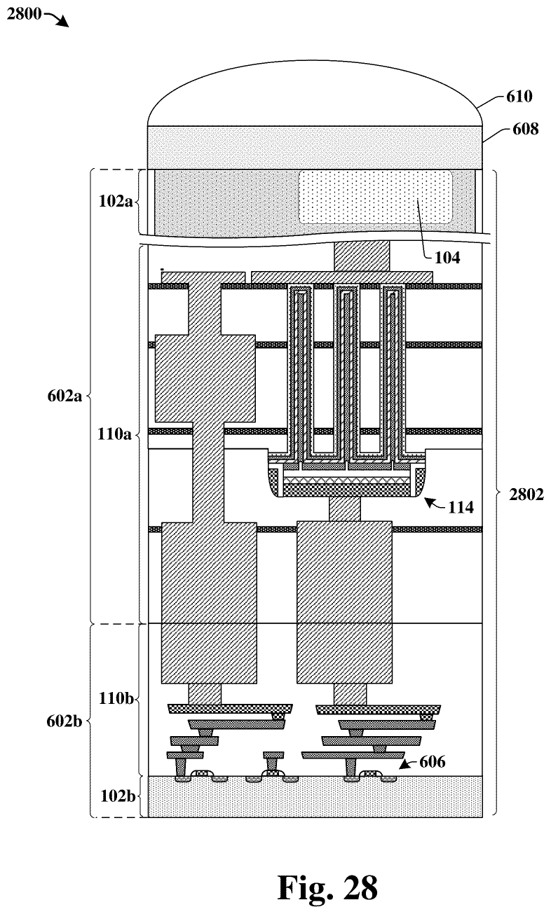

As shown in cross-sectional view 2800 of FIG. 28, in some additional embodiments, the first substrate 102a may be bonded to a second substrate 102b to form a multi-tiered integrated chip structure 2802. In some embodiments, the first substrate 102a may comprise a plurality of image sensing elements 104 and the second substrate 102b may comprise one or more pixel support devices 606 (e.g., reset transistors, source-follower transistors, row-select transistors, etc.). In other embodiments (not shown), the first substrate 102a may comprise one or more pixel support devices and the second substrate 102b may comprise a plurality of image sensing elements. After bonding, the multi-tiered integrated chip structure 2802 may be singulated to form one or more integrated chip die (not shown). After singulation, a plurality of color filters 608 may be formed over the first substrate 102a and a plurality of micro-lenses 610 may be formed over the plurality of color filters 608.

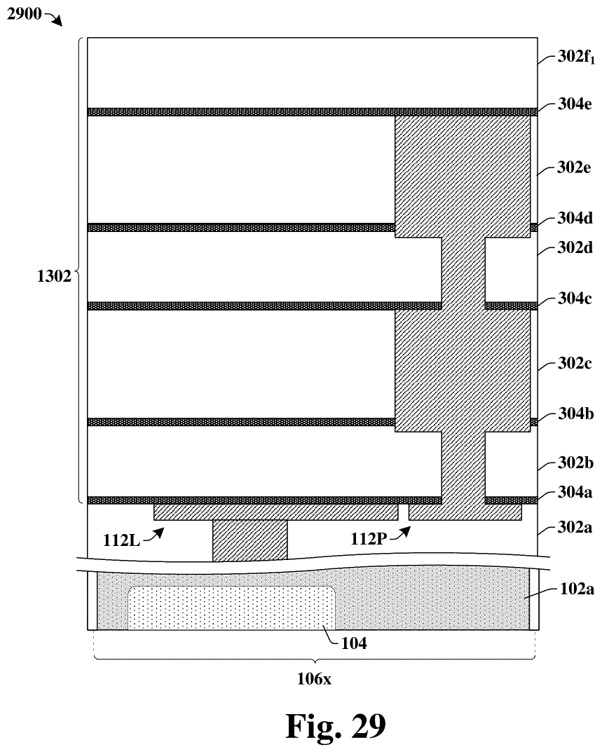

FIGS. 29-36 illustrate cross-sectional views 2900-3600 of some additional embodiments of a method of forming a three-dimensional capacitor within a pixel region of an image sensor integrated chip. Although FIGS. 29-36 are described in relation to a method, it will be appreciated that the structures disclosed in the method are not limited to the method, but instead may stand alone as structures independent of the method.

As shown in cross-sectional view 2900 of FIG. 29, a first substrate 102a is provided. The first substrate 102a comprises a plurality of pixel regions 106x arranged within a pixel array. In some embodiments, a plurality of image sensing elements 104 are formed within the plurality of pixel regions 106x. In other embodiments (not shown), the first substrate 102a may be devoid of image sensing elements. In some such embodiments, the one or more pixel support devices (e.g., reset transistors, source-follower transistors, row-select transistors, etc.) may be formed onto the first substrate 102a.

A lower interconnect structure 112L is formed within a first ILD layer 302a formed over the first substrate 102a. A lower ILD structure 1302 is formed over the first ILD layer 302a. In some embodiments, the lower ILD structure 1302 may be formed by forming a first etch stop layer (ESL) 304a over the first ILD layer 302a, a second ILD layer 302b over the first ESL 304a, a second ESL 304b over the second ILD layer 302b, a third ILD layer 302c over the second ESL 304b, a third ESL 304c over the third ILD layer 302c, a fourth ILD layer 302d over the third ESL 304c, a fourth ESL 304d over the fourth ILD layer 302d, a fifth ILD layer 302e over the fourth ESL 304d, a fifth ESL 304e over the fifth ILD layer 302e, and a lower sixth ILD layer 302f₁ over the fifth ESL 304e. A peripheral interconnect structure 112P is formed to extend through the first ILD layer 302a, the second ILD layer 302b, the second ESL 304b, and the third ILD layer 302c, the third ESL 304c, the fourth ILD layer 302d, the fourth ESL 304d, and the fifth ILD layer 302e. In some embodiments, the lower interconnect structure 112L and the peripheral interconnect structure 112P may be formed using damascene processes (e.g., a single damascene process and/or a dual damascene process).

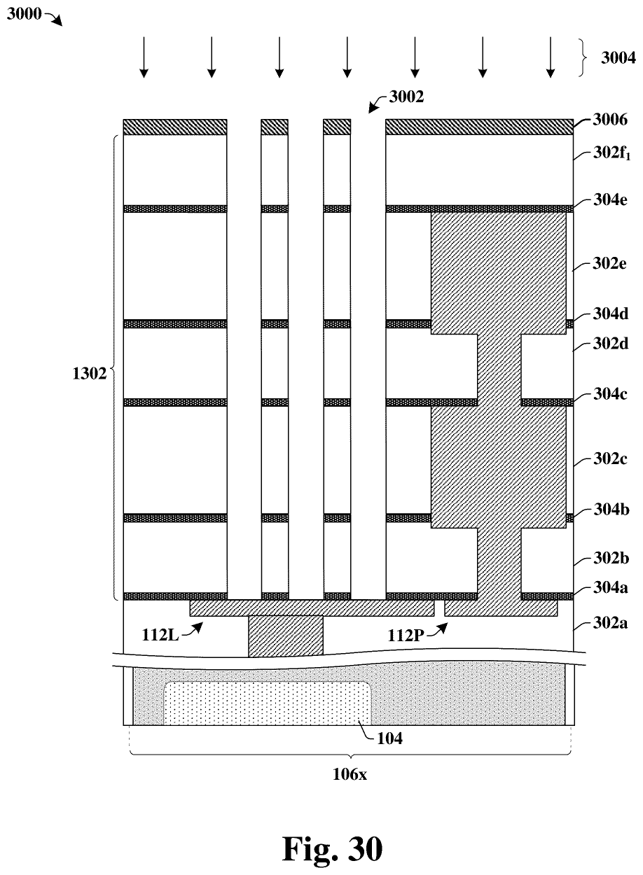

As shown in cross-sectional view 3000 of FIG. 30, the lower ILD structure 1302 is selectively patterned by way of an etching process to form an opening 3002 that vertically extends through the sixth ILD layer 302f₁, the fifth ESL 304e, the fifth ILD layer 302e, the fourth ESL 304d, the fourth ILD layer 302d, the third ESL 304c, the third ILD layer 302c, the second ESL 304b, the second ILD layer 302b, and the first ESL 304a. In some embodiments, the etching process may expose the sixth ILD layer 302f₁ to one or more etchants 3004 according to a mask 3006.

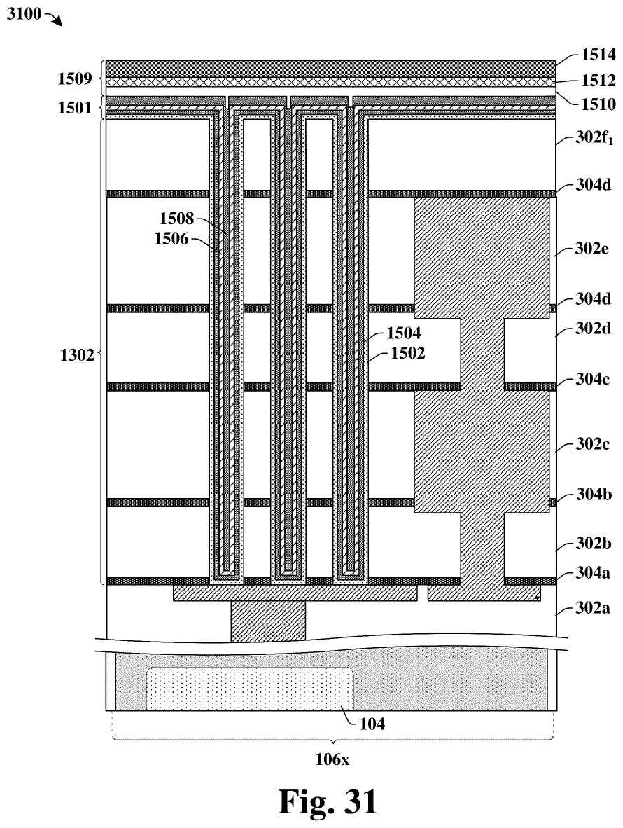

As shown in cross-sectional view 3100 of FIG. 31, a capacitor stack 1501 is formed within the opening 3002 and over a top of the lower ILD structure 1302. In some embodiments, the capacitor stack 1501 may comprise a capacitor barrier layer 1502, a first capacitor electrode layer 1504 is formed over the capacitor barrier layer 1502, a capacitor dielectric layer 1506 formed over the first capacitor electrode layer 1504, and a second capacitor electrode layer 1508 formed over the capacitor dielectric layer 1506. In some embodiments, the second capacitor electrode layer 1508 is formed to have one or more interior surfaces that form recesses 306 over bottoms of the second capacitor electrode layer 1508.

In some embodiments, a capacitor capping stack 1509 may be formed by further forming a first upper capacitor dielectric layer 1510 over the second capacitor electrode layer 1508, a second upper capacitor dielectric layer 1512 over the first upper capacitor dielectric layer 1510, and a third upper capacitor dielectric layer 1514 over the second upper capacitor dielectric layer 1512.

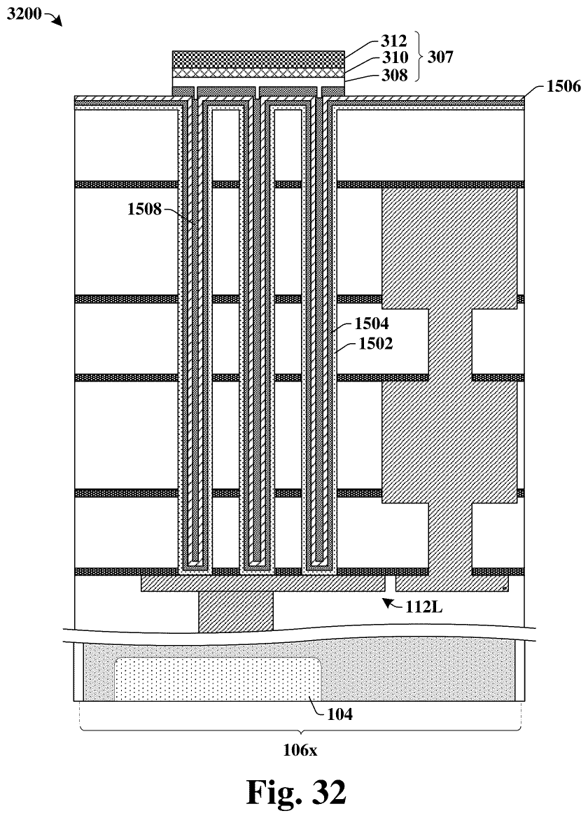

As shown in cross-sectional view 3200 of FIG. 32, the capacitor capping stack (e.g., 1509 of FIG. 31) is patterned according to an etching process to form a capacitor cap 307. The etching process removes parts of the capacitor upper electrode layer to form a second electrode 120, parts of the first upper capacitor dielectric layer to form a first upper dielectric 308, parts of the second upper capacitor dielectric layer to form a second upper dielectric 310, and parts of the third upper capacitor dielectric layer to form a third upper dielectric 312.

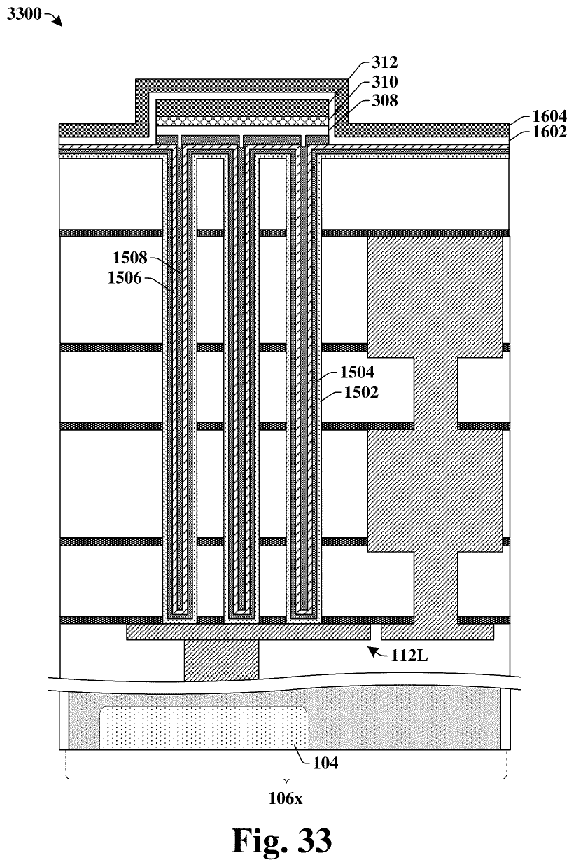

As shown in cross-sectional view 3300 of FIG. 33, a first hard mask 1602 is formed onto the capacitor dielectric layer 1506 and along sidewalls and an upper surface of the capacitor cap 307. A second hard mask 1604 is formed along sidewalls and an upper surface of the first hard mask 1602.

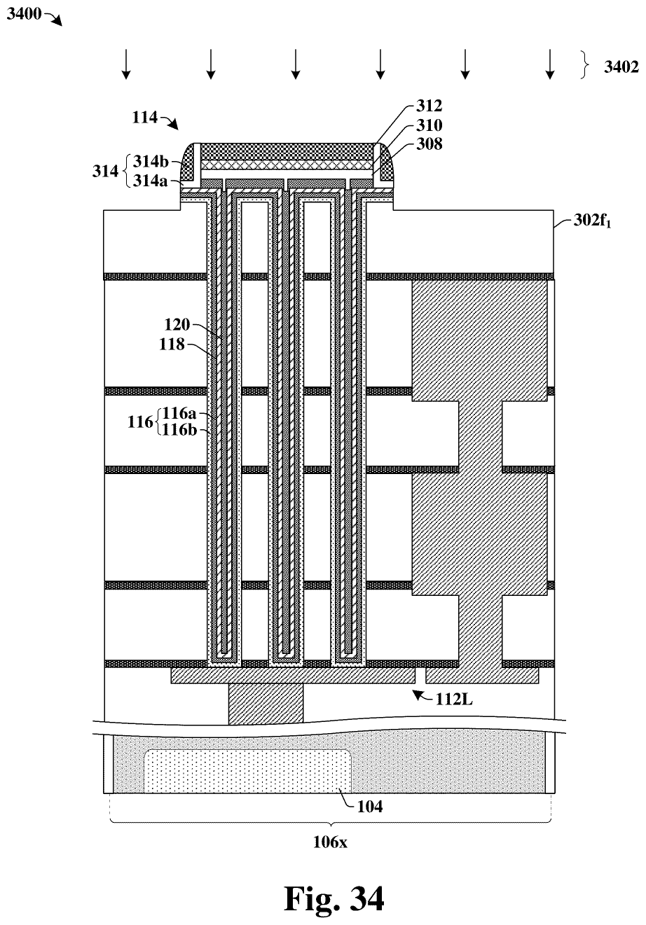

As shown in cross-sectional view 3400 of FIG. 34, the first hard mask (e.g., 1602 of FIG. 33) and the second hard mask (e.g., 1604 of FIG. 33) are etched using one or more etchants 3402. The one or more etchants remove horizontally extending segments of the first hard mask and the second hard mask to form one or more sidewall spacers 314 along opposing sides of the capacitor cap 307 and the second electrode 120. The one or more sidewall spacers 314 include a first dielectric spacer layer 314a and a second dielectric spacer layer 314b on the first dielectric spacer layer 314a.

The one or more etchants 3402 further etch the capacitor dielectric layer to form a capacitor dielectric 118, the first capacitor electrode layer to form a lower capacitor metal 116a, and the capacitor barrier layer to form a capacitor barrier 116b. In some embodiments, the etchants may also etch the lower sixth ILD layer 302f₁ so as to recess a part of the lower sixth ILD layer 302f₁ a non-zero distance below an outermost sidewall of the capacitor barrier 116b.

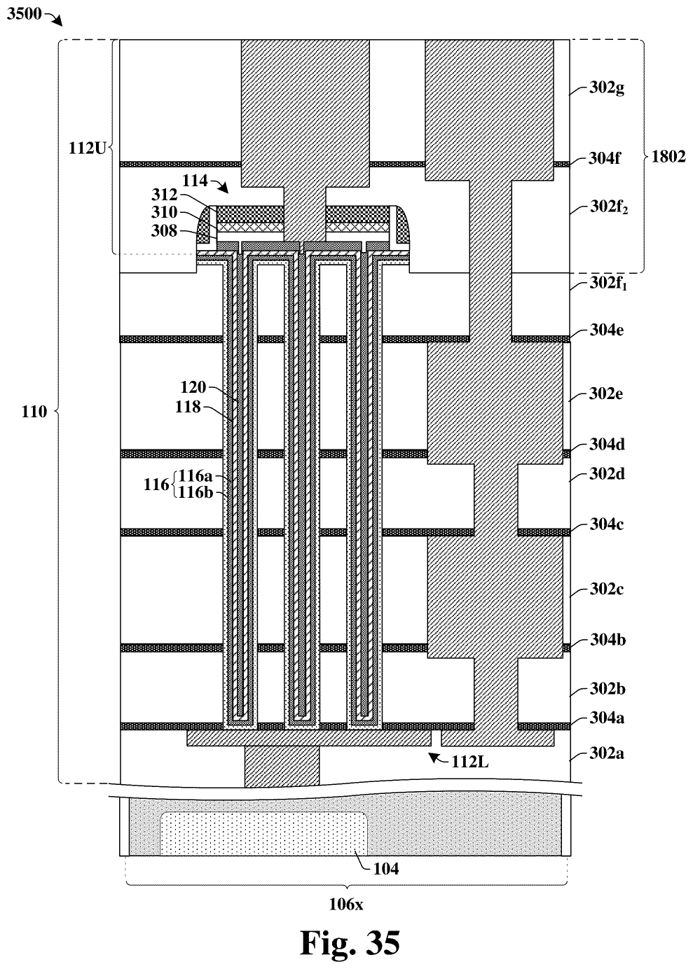

As shown in cross-sectional view 3500 of FIG. 35, an upper ILD structure 1802 is formed onto the lower sixth ILD layer 302f₁ and over the 3D capacitor 114. In some embodiments, the upper ILD structure 1802 is formed by forming an upper sixth ILD layer 302f₂ on the lower sixth ILD layer 302f₁, a sixth ESL 304f on the upper sixth ILD layer 302f₂, and a seventh ILD layer 302g on the sixth ESL 304f.

An upper interconnect structure 112U is formed onto the 3D capacitor 114. The upper interconnect structure 112U is formed to vertically extend through the within the seventh ILD layer 302g, the sixth ESL 304f, and the upper sixth ILD layer 302f₂. In some embodiments, the upper interconnect structure 112U comprises a conductive via and a conductive wire.

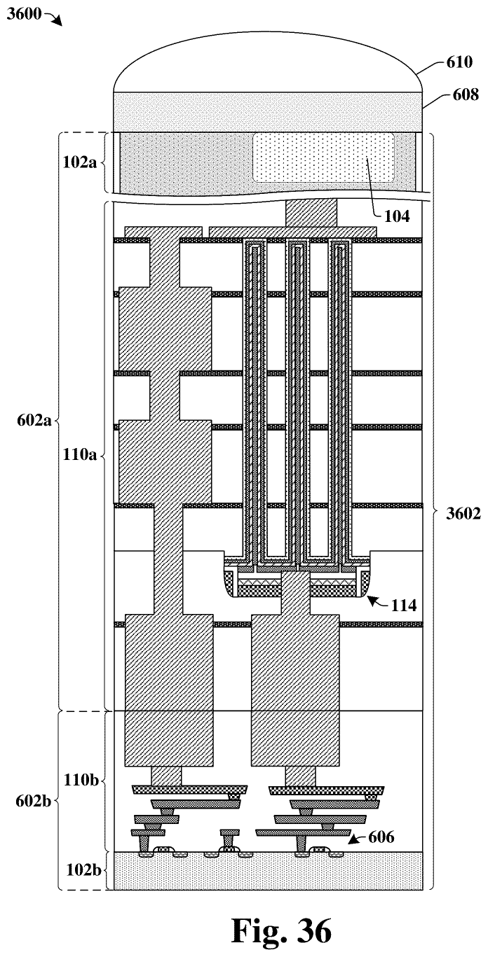

As shown in cross-sectional view 3600 of FIG. 36, in some additional embodiments, the first substrate 102a may be bonded to a second substrate 102b to form a multi-tiered integrated chip structure 3602. In some embodiments, the first substrate 102a may comprise a plurality of image sensing elements 104 and the second substrate 102b may comprise one or more pixel support devices (e.g., reset transistors, source-follower transistors, row-select transistors, etc.). In other embodiments (not shown), the first substrate 102a may comprise one or more pixel support devices and the second substrate 102b may comprise a plurality of image sensing elements 104. After bonding, the multi-tiered integrated chip structure 3602 may be singulated to form one or more integrated chip die (not shown). After singulation, a plurality of color filters 608 may be formed over the first substrate 104a and a plurality of micro-lenses 610 may be formed over the plurality of color filters 608.

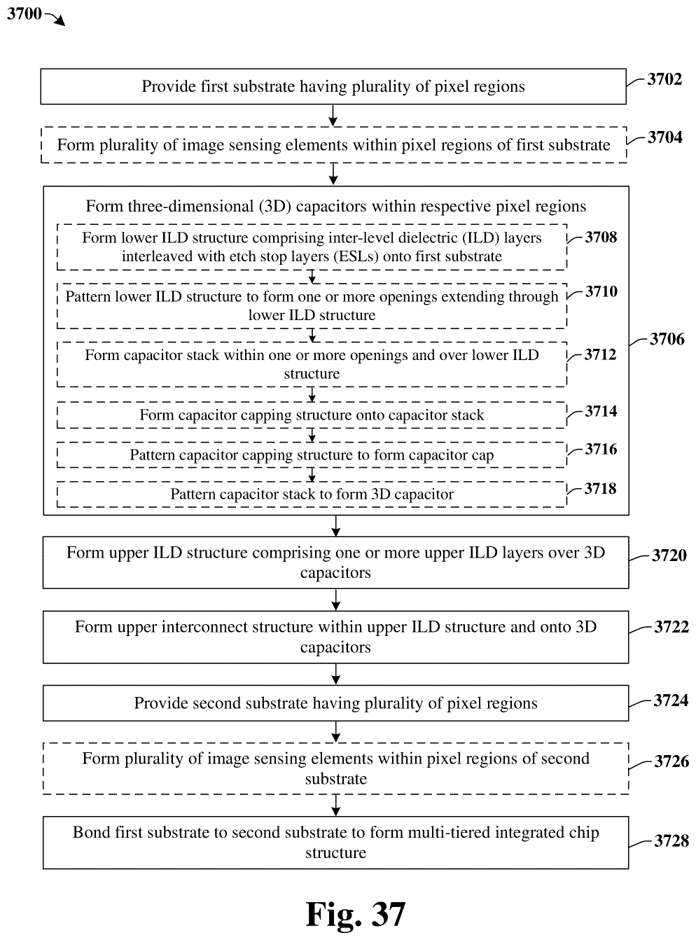

FIG. 37 illustrates a flow diagram of some embodiments of a method 3700 of forming a three-dimensional capacitor within a pixel region of an image sensor integrated chip.

While the disclosed method 3700 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 3702, a first substrate is provided having a plurality of pixel regions. FIG. 13 illustrates a cross-sectional view 1300 of some embodiments corresponding to act 3702. FIG. 21 illustrates a cross-sectional view 2100 of some alternative embodiments corresponding to act 3702. FIG. 29 illustrates a cross-sectional view 2900 of some additional alternative embodiments corresponding to act 3702.

At act 3704, a plurality of image sensing elements may be formed within the plurality of pixel regions of the first substrate in some embodiments. FIG. 13 illustrates a cross-sectional view 1300 of some embodiments corresponding to act 3704. FIG. 21 illustrates a cross-sectional view 2100 of some alternative embodiments corresponding to act 3704. FIG. 29 illustrates a cross-sectional view 2900 of some additional alternative embodiments corresponding to act 3704.

At act 3706, a plurality of three-dimensional (3D) capacitors are formed within respective ones of the plurality of pixel regions. In some embodiments, the plurality of three-dimensional capacitors may be formed according to acts 3708-3718.

At act 3708, a lower inter-level dielectric (ILD) structure comprising lower ILD layers interleaved with lower etch stop layers (ESLs) is formed onto the substrate. FIG. 13 illustrates a cross-sectional view 1300 of some embodiments corresponding to act 3708. FIG. 21 illustrates a cross-sectional view 2100 of some alternative embodiments corresponding to act 3708. FIG. 29 illustrates a cross-sectional view 2900 of some additional alternative embodiments corresponding to act 3708.

At act 3710, the lower ILD structure is patterned to form one or more openings extending through the lower ILD structure. FIG. 14 illustrates a cross-sectional view 1400 of some embodiments corresponding to act 3710. FIG. 22 illustrates a cross-sectional view 2200 of some alternative embodiments corresponding to act 3710. FIG. 30 illustrates a cross-sectional view 3000 of some additional alternative embodiments corresponding to act 3710.

At act 3712, a capacitor stack is formed within the one or more openings and over the lower ILD structure. FIG. 15 illustrates a cross-sectional view 1500 of some embodiments corresponding to act 3712. FIG. 23 illustrates a cross-sectional view 2300 of some alternative embodiments corresponding to act 3712. FIG. 31 illustrates a cross-sectional view 3100 of some additional alternative embodiments corresponding to act 3712.

At act 3714, a capacitor capping structure is formed onto the capacitor stack. FIG. 15 illustrates a cross-sectional view 1500 of some embodiments corresponding to act 3714. FIG. 23 illustrates a cross-sectional view 2300 of some alternative embodiments corresponding to act 3714. FIG. 31 illustrates a cross-sectional view 3100 of some additional alternative embodiments corresponding to act 3714.

At act 3716, the capacitor capping structure is patterned to form a capacitor cap. FIG. 16 illustrates a cross-sectional view 1600 of some embodiments corresponding to act 3716. FIG. 24 illustrates a cross-sectional view 2400 of some alternative embodiments corresponding to act 3716. FIG. 32 illustrates a cross-sectional view 3200 of some additional alternative embodiments corresponding to act 3716.

At act 3718, the capacitor stack is patterned to form a 3D capacitor. FIG. 17 illustrates a cross-sectional view 1700 of some embodiments corresponding to act 3718. FIG. 26 illustrates a cross-sectional view 2600 of some alternative embodiments corresponding to act 3718. FIG. 34 illustrates a cross-sectional view 3400 of some additional alternative embodiments corresponding to act 3718.

At act 3720, an upper ILD structure comprising one or more upper ILD layers are formed over the 3D capacitors. FIG. 18 illustrates a cross-sectional view 1800 of some embodiments corresponding to act 3720. FIG. 27 illustrates a cross-sectional view 2700 of some alternative embodiments corresponding to act 3720. FIG. 35 illustrates a cross-sectional view 3500 of some additional alternative embodiments corresponding to act 3720.

At act 3722, an upper interconnect structure is formed within an upper ILD structure and onto the 3D capacitors. FIG. 19 illustrates a cross-sectional view 1900 of some embodiments corresponding to act 3722. FIG. 27 illustrates a cross-sectional view 2700 of some alternative embodiments corresponding to act 3722. FIG. 35 illustrates a cross-sectional view 3500 of some additional alternative embodiments corresponding to act 3722.

At act 3724, a second substrate is provided having a plurality of pixel regions.

At act 3726, a plurality of image sensing elements may be formed within the plurality of pixel regions of the second substrate in some embodiments.

At act 3728, the first substrate is bonded to the second substrate to form a multi-tiered integrated chip structure. In some embodiments, the first substrate may comprise a plurality of image sensing elements within a pixel array. In other embodiments, the second substrate may comprise a plurality of image sensing elements within a pixel array. FIG. 20 illustrates a cross-sectional view 2000 of some embodiments corresponding to act 3728. FIG. 28 illustrates a cross-sectional view 2800 of some alternative embodiments corresponding to act 3728. FIG. 36 illustrates a cross-sectional view 3600 of some additional alternative embodiments corresponding to act 3728.

Accordingly, the present disclosure relates to a method of forming a three-dimensional (3D) capacitor within a pixel region of an image sensor integrated chip.

In some embodiments, the present disclosure relates to an image sensor integrated chip (IC) structure. The image sensor IC structure includes a plurality of image sensing elements respectively disposed within a plurality of pixel regions of a pixel array within a substrate; an inter-level dielectric (ILD) structure disposed on a surface of the substrate and surrounding one or more interconnects; and a plurality of three-dimensional (3D) capacitors arranged within respective ones of the plurality of pixel regions and coupled to one of the plurality of image sensing elements by the one or more interconnects, the plurality of 3D capacitors including a base region extending in parallel to the surface of the substrate and one or more fingers extending outward from the base region along a direction perpendicular to the surface of the substrate. In some embodiments, respective ones of the plurality of 3D capacitors are entirely confined within an overlying one of the plurality of pixel regions. In some embodiments, the ILD structure includes a plurality of inter-level dielectric (ILD) layers separated by one or more etch stop layers (ESL), the plurality of 3D capacitors vertically extending through two of the plurality of ILD layers. In some embodiments, a first 3D capacitor of the plurality of 3D capacitors is arranged within a first pixel region of the plurality of pixel regions; and a peripheral interconnect structure is arranged within the first pixel region, the first 3D capacitor is laterally separated from the peripheral interconnect structure by the ILD structure. In some embodiments, the peripheral interconnect structure includes a conductive via, the first 3D capacitor vertically extending from below a top of the conductive via to below a bottom of the conductive via. In some embodiments, the peripheral interconnect structure further includes an interconnect wire having a larger width than the conductive via, the first 3D capacitor vertically extending from above a top of the interconnect wire to below a bottom of the interconnect wire. In some embodiments, the one or more fingers respectively have a rectangular shape, as viewed in a plan-view. In some embodiments, the one or more fingers respectively have a circular shape, as viewed in a plan-view. In some embodiments, the one or more fingers respectively have an enclosed shape that continuously extends around a column of the ILD structure, as viewed in a plan-view. In some embodiments, the plurality of 3D capacitors are respectively implemented within a lateral overflow integration capacitor (LOFIC) pixel. In some embodiments, the image sensor IC structure further includes a second substrate; a second ILD structure on the second substrate, the ILD structure being bonded to the second ILD structure by a bonding region that includes conductive interfaces and dielectric interfaces; and a second plurality of 3D capacitors, the plurality of 3D capacitors being arranged within the ILD structure and the second plurality of 3D capacitors being arranged within the second ILD structure.

In other embodiments, the present disclosure relates to an image sensor IC structure. The image sensor IC structure includes a plurality of image sensing elements respectively disposed within a plurality of pixel regions of a pixel array within a substrate; an inter-level dielectric (ILD) structure disposed on the substrate and surrounding one or more interconnects, the ILD structure including a plurality of ILD layers separated by one or more etch stop layers (ESL); and a plurality of three-dimensional (3D) capacitors in arranged within a respective one of the plurality of pixel regions below one of the plurality of image sensing elements, the plurality of 3D capacitors having a lower surface arranged between an outermost sidewall and an outer sidewall facing a same direction. In some embodiments, respective ones of the plurality of 3D capacitors are set back from opposing edges of an overlying one of the plurality of pixel regions by non-zero distances. In some embodiments, the ILD structure includes a first ILD layer having a first upper surface below the lower surface and a second upper surface laterally outside of the lower surface, the first upper surface being over the second upper surface; and a second ILD layer arranged along a sidewall of the first ILD layer and over the second upper surface. In some embodiments, the image sensor IC structure further includes a second substrate; a second ILD structure on the second substrate and vertically between the ILD structure and the second substrate; and the plurality of 3D capacitors being arranged within the second ILD structure. In some embodiments, the plurality of 3D capacitors vertically extend from below the second substrate to above the second substrate and within the second ILD structure. In some embodiments, the outer sidewall vertically extends from above one of the plurality of ILD layers to below the one of the plurality of ILD layers.

In yet other embodiments, the present disclosure relates to a method of forming an image sensor IC structure. The method includes providing a first substrate having a plurality of pixel regions within a pixel array; forming one or more ILD layers on the first substrate; forming an opening extending vertically through the one or more ILD layers, the opening being laterally set-back from opposing sides of one of the plurality of pixel regions by non-zero distances; forming a capacitor stack within the opening and over the one or more ILD layers; and patterning the capacitor stack to form a capacitor having a horizontally extending segment over the one or more ILD layers and a vertically extending segment extending through the one or more ILD layers. In some embodiments, the vertically extending segment includes a first electrode separated from a second electrode by a capacitor dielectric; the first electrode, the second electrode, and the capacitor dielectric concentrically surrounding the one or more ILD layers. In some embodiments, the method further includes forming a plurality of image sensing elements within a second substrate, the plurality of image sensing elements being formed within the plurality of pixel regions; and bonding the first substrate to the second substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor integrated chip (IC) structure, comprising:
a plurality of image sensing elements respectively disposed within a plurality of pixel regions of a pixel array within a substrate;
an inter-level dielectric (ILD) structure disposed on a surface of the substrate and surrounding one or more interconnects; and
a plurality of three-dimensional (3D) capacitors arranged within respective ones of the plurality of pixel regions and coupled to one of the plurality of image sensing elements by the one or more interconnects, wherein the plurality of 3D capacitors comprise a base region extending in parallel to the surface of the substrate and one or more fingers extending outward from the base region along a direction perpendicular to the surface of the substrate.

2. The image sensor IC of claim 1, wherein respective ones of the plurality of 3D capacitors are entirely confined within an overlying one of the plurality of pixel regions.

3. The image sensor IC of claim 1, wherein the ILD structure comprises a plurality of inter-level dielectric (ILD) layers separated by one or more etch stop layers (ESL), the plurality of 3D capacitors vertically extending through two of the plurality of ILD layers.

4. The image sensor IC of claim 1,
wherein a first 3D capacitor of the plurality of 3D capacitors is arranged within a first pixel region of the plurality of pixel regions; and
wherein a peripheral interconnect structure is arranged within the first pixel region, the first 3D capacitor being laterally separated from the peripheral interconnect structure by the ILD structure.

5. The image sensor IC of claim 4, wherein the peripheral interconnect structure comprises a conductive via, the first 3D capacitor vertically extending from below a top of the conductive via to below a bottom of the conductive via.

6. The image sensor IC of claim 5, wherein the peripheral interconnect structure further comprises an interconnect wire having a larger width than the conductive via, the first 3D capacitor vertically extending from above a top of the interconnect wire to below a bottom of the interconnect wire.

7. The image sensor IC of claim 1, wherein the one or more fingers respectively have a rectangular shape, as viewed in a plan-view.

8. The image sensor IC of claim 1, wherein the one or more fingers respectively have a circular shape, as viewed in a plan-view.

9. The image sensor IC of claim 1, wherein the one or more fingers respectively have an enclosed shape that continuously extends around a column of the ILD structure, as viewed in a plan-view.

10. The image sensor IC of claim 1, wherein the plurality of 3D capacitors are respectively implemented within a lateral overflow integration capacitor (LOFIC) pixel.

11. The image sensor IC of claim 1, further comprising:
a second substrate;
a second ILD structure on the second substrate, wherein the ILD structure is bonded to the second ILD structure by a bonding region that includes conductive interfaces and dielectric interfaces; and
a second plurality of 3D capacitors, wherein the plurality of 3D capacitors are arranged within the ILD structure and the second plurality of 3D capacitors are arranged within the second ILD structure.

12. An image sensor integrated chip (IC) structure, comprising:
a plurality of image sensing elements respectively disposed within a plurality of pixel regions of a pixel array within a substrate;
an inter-level dielectric (ILD) structure disposed on the substrate and surrounding one or more interconnects, the ILD structure comprising a plurality of ILD layers separated by one or more etch stop layers (ESL); and
a plurality of three-dimensional (3D) capacitors in arranged within a respective one of the plurality of pixel regions below one of the plurality of image sensing elements, wherein the plurality of 3D capacitors comprise a lower surface arranged between an outermost sidewall and an outer sidewall facing a same direction.

13. The image sensor IC of claim 12, wherein respective ones of the plurality of 3D capacitors are set back from opposing edges of an overlying one of the plurality of pixel regions by non-zero distances.

14. The image sensor IC of claim 12, wherein the ILD structure comprises:
a first ILD layer having a first upper surface below the lower surface and a second upper surface laterally outside of the lower surface, the first upper surface being over the second upper surface; and
a second ILD layer arranged along a sidewall of the first ILD layer and over the second upper surface.

15. The image sensor IC of claim 12, further comprising:
a second substrate;
a second ILD structure on the second substrate and vertically between the ILD structure and the second substrate; and
wherein the plurality of 3D capacitors are arranged within the second ILD structure.

16. The image sensor IC of claim 15, wherein the plurality of 3D capacitors vertically extend from below the second substrate to above the second substrate and within the second ILD structure.

17. The image sensor IC of claim 12, wherein the outer sidewall vertically extends from above one of the plurality of ILD layers to below the one of the plurality of ILD layers.

18. A method of forming an image sensor integrated chip (IC), comprising:
providing a first substrate having a plurality of pixel regions within a pixel array;
forming one or more ILD layers on the first substrate;
forming an opening extending vertically through the one or more ILD layers, wherein the opening is laterally set-back from opposing sides of one of the plurality of pixel regions by non-zero distances;
forming a capacitor stack within the opening and over the one or more ILD layers; and
patterning the capacitor stack to form a capacitor having a horizontally extending segment over the one or more ILD layers and a vertically extending segment extending through the one or more ILD layers.

19. The method of claim 18,
wherein the vertically extending segment comprises a first electrode separated from a second electrode by a capacitor dielectric; and
wherein the first electrode, the second electrode, and the capacitor dielectric concentrically surround the one or more ILD layers.

20. The method of claim 18, further comprising:
forming a plurality of image sensing elements within a second substrate, the plurality of image sensing elements being formed within the plurality of pixel regions; and
bonding the first substrate to the second substrate.
